(19) United States
(12) Patent Application Publication
(10) Pub. No.: US 2024/0142870 A1
(43) Pub. Date: May 2, 2024

(54) ALUMINUM OXIDE CARBON HYBRID HARDMASKS AND METHODS FOR MAKING THE SAME

(71) Applicant: Applied Materials, Inc., Santa Clara, CA (US)

(72) Inventors: Yung-chen LIN, Gardena, CA (US); Zhiyu HUANG, Sunnyvale, CA (US); Chi-I LANG, Cupertino, CA (US); Ho-yung HWANG, Cupertino, CA (US)

(73) Assignee: Applied Materials, Inc., Santa Clara, CA (US)

(21) Appl. No.: 18/237,648

(22) Filed: Aug. 24, 2023

Related U.S. Application Data
(60) Provisional application No. 63/419,589, filed on Oct. 26, 2022.

(51) Int. Cl. G03F 1/38; G03F 1/46; G03F 1/76; G03F 1/80

(52) U.S. Cl. CPC G03F 1/38; G03F 1/46; G03F 1/76; G03F 1/80

(57) ABSTRACT

Embodiments of the present disclosure generally relate to methods for enhancing carbon hardmask to have improved etching selectivity and profile control. In some embodiments, a method of treating a carbon hardmask layer is provided and includes positioning a workpiece within a process region of a processing chamber, where the workpiece has a carbon hardmask layer disposed on or over an underlying layer, and treating the carbon hardmask layer by exposing the workpiece to a sequential infiltration synthesis (SIS) process to produce an aluminum oxide carbon hybrid hardmask which is denser than the carbon hardmask layer. The SIS process includes exposing and infiltrating the carbon hardmask layer with an aluminum precursor, purging to remove gaseous remnants, exposing and infiltrating the carbon hardmask layer to an oxidizing agent to produce an aluminum oxide coating disposed on inner surfaces of the carbon hardmask layer, and purging the process region to remove gaseous remnants.

### CROSS-REFERENCE TO RELATED APPLICATIONS

This application claims benefit to U.S. Prov. Appl. No. 63/419,589, filed Oct. 26, 2022, which is incorporated herein by reference in its entirety.

### BACKGROUND

### Field

Embodiments of the present disclosure generally relate to photoresist technology, and more specifically, relate to methods for enhancing photoresist to have improved etching selectivity and profile control.

### Description of the Related Art

Integrated circuits have evolved into complex devices that can include millions of components (e.g., transistors, capacitors and resistors) on a single chip. Photolithography may be used to form components on a chip. Generally the process of photolithography involves forming a photoresist layer on a substrate. The photoresist layer may be formed by, for example, spin-coating. The photoresist layer may include a resist resin and a photoacid generator. The photoacid generator, upon exposure to electromagnetic radiation in the subsequent exposure stage, alters the solubility of the photoresist in the development process. The electromagnetic radiation may have any suitable wavelength, such as a wavelength in the extreme ultra violet region, and can be from any suitable source, e.g., a 193 nm ArF laser, an electron beam, an ion beam, or other source. Excess solvent may then be removed in a pre-exposure bake process.

During an exposure stage, a photomask or reticle may be used to selectively expose certain regions of a photoresist layer disposed on the substrate to electromagnetic radiation. Other exposure methods may be maskless exposure methods. Exposure to light may decompose the photoacid generator, which generates acid and results in a latent acid image in the resist resin. After exposure, the substrate may be heated in a post-exposure bake process. During the post-exposure bake process, the acid generated by the photoacid generator reacts with the resist resin in the photoresist layer, changing the solubility of the resist of the photoresist layer during a subsequent development process.

After the post-exposure bake, the substrate and the photoresist layer are developed and rinsed. Subsequently, a patterned photoresist layer is then formed on the substrate. Openings are defined within the patterned photoresist layer, after the development and rinse processes, exposing the underlying target material for etching to transfer features onto a target material. Factors such as inaccurate control or low resolution of the lithography exposure process, or resilience of the patterned layer, may cause poor critical dimension of the patterned photoresist layer, resulting in unacceptable line width roughness (LWR). Large line width roughness (LWR) of the patterned photoresist layer may result in inaccurate feature transfer to the target material, which can eventually lead to premature device failure and yield loss.

A carbon-based hardmask is one specific type of photoresist material used in the industry. However, the existing materials of carbon-based hardmasks have limited etch selectivity between the PR layer and the respective underlayer. Carbon-based hardmasks have a limited etch resistance and often become slightly deteriorated or compromised during the etching process. Furthermore, the existing materials of carbon-based hardmasks suffer from pattern transfer defects and moderate line edge roughness (LER) and line width roughness (LWR).

Therefore, there is a need for improved carbon-based hardmasks which overcome these shortcomings, and methods for preparing such carbon-based hardmasks.

### SUMMARY

Embodiments of the present disclosure generally relate to hardmasks having improved etching selectivity and profile control and methods for preparing the hardmasks. The hardmask is an aluminum oxide carbon hybrid hardmask which can be prepared from a carbon hardmask. For example, the carbon hardmask layer can be treated by a sequential infiltration synthesis (SIS) process to make or otherwise produce the aluminum oxide carbon hybrid hardmask.

In one or more embodiments, a method of treating a carbon hardmask layer is provided and includes positioning a workpiece within a process region of a processing chamber, wherein the workpiece has a carbon hardmask layer disposed on or over an underlayer, and treating the carbon hardmask layer by exposing the workpiece to a SIS process to produce an aluminum oxide carbon hybrid hardmask which is denser than the carbon hardmask layer. The SIS process includes one or more infiltration cycles, and each of the infiltration cycles includes exposing the carbon hardmask layer to an aluminum precursor, infiltrating the carbon hardmask layer with the aluminum precursor via pores contained in the carbon hardmask layer, and purging the process region to remove gaseous remnants containing the aluminum precursor, exposing the carbon hardmask layer to an oxidizing agent, infiltrating the carbon hardmask layer with the oxidizing agent via the pores contained in the carbon hardmask layer to produce an aluminum oxide coating disposed on inner surfaces of the carbon hardmask layer, and purging the process region to remove gaseous remnants containing the oxidizing agent.

In other embodiments, a method of forming a device is provided and includes positioning a workpiece within a process region of a processing chamber, wherein the workpiece contains a carbon hardmask layer disposed on or over an underlayer, a silicon-containing hardmask disposed on or over the carbon hardmask layer, and a patterned photoresist layer having a feature pattern disposed on the silicon-containing hardmask. The method also includes etching the silicon-containing hardmask and the carbon hardmask layer to each have the feature pattern of the patterned photoresist layer, treating the carbon hardmask layer by exposing the workpiece to a SIS process to produce an aluminum oxide carbon hybrid hardmask which is denser than the carbon hardmask layer, and then etching the underlayer to have the feature pattern of the patterned photoresist layer.

In some embodiments, a method of forming a device is provided and includes positioning a workpiece within a process region of a processing chamber, wherein the workpiece contains a metal or metal nitride layer disposed on or over a substrate, a silicon-containing hardmask disposed on or over the metal or metal nitride layer, and a patterned photoresist layer having a feature pattern disposed on the silicon-containing hardmask. The method further includes etching the silicon-containing hardmask to have the feature pattern of the patterned photoresist layer, removing the patterned photoresist layer from the silicon-containing hardmask, and depositing a carbon hardmask layer at least into the feature pattern of the patterned photoresist layer. The method also includes treating the carbon hardmask layer by exposing the workpiece to a SIS process to produce an aluminum oxide carbon hybrid hardmask which is denser than the carbon hardmask layer, and then etching the silicon-containing hardmask to produce a reverse pattern within the aluminum oxide carbon hybrid hardmask.

In other embodiments, a method of forming a device is provided and includes positioning a workpiece within a process region of a processing chamber, wherein the workpiece contains a metal or metal nitride layer disposed on or over a substrate, a silicon-containing hardmask disposed on or over the metal or metal nitride layer, and a patterned photoresist layer having a feature pattern disposed on the silicon-containing hardmask. The method also includes etching the silicon-containing hardmask to have the feature pattern of the patterned photoresist layer, removing the patterned photoresist layer from the silicon-containing hardmask, and depositing a carbon hardmask layer into the feature pattern of the patterned photoresist layer and onto an upper surface of the patterned photoresist layer. The method further includes depositing a photoresist-antireflective coating (PR-ARC) layer on a first portion of the carbon hardmask layer while leaving exposed a second portion of the carbon hardmask layer. Also, the method includes etching the second portion of the carbon hardmask layer while maintaining the PR-ARC layer and the first portion of the carbon hardmask layer on the workpiece during a first mask etch process and etching the PR-ARC layer while maintaining the first portion of the carbon hardmask layer on the workpiece during a second mask etch process. The method further includes treating the first portion of the carbon hardmask layer by exposing the workpiece to a SIS process to produce an aluminum oxide carbon hybrid hardmask which is denser than the carbon hardmask layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1C depict cross-sectional views of a workpiece at different stages of a treatment process, as described and discussed in one or more embodiments herein.

FIGS. 2A-2D depict cross-sectional views of another workpiece at different stages of a process for preparing or otherwise forming a device, as described and discussed in one or more embodiments herein.

FIGS. 3A-3F depict cross-sectional views of another workpiece at different stages of a process for preparing or otherwise forming a device, as described and discussed in one or more embodiments herein.

FIGS. 4A-4G depict cross-sectional views of another workpiece at different stages of a process for preparing or otherwise forming a device, as described and discussed in one or more embodiments herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to hardmasks having improved etching selectivity and profile control and methods for preparing the hardmasks. The hardmask is an aluminum oxide carbon hybrid hardmask can be prepared from a carbon hardmask. In one or more embodiments, the carbon hardmask layer is treated by a sequential infiltration synthesis (SIS) process to make or otherwise produce the aluminum oxide carbon hybrid hardmask. The aluminum oxide carbon hybrid hardmask is denser than the carbon hardmask layer used to form the aluminum oxide carbon hybrid hardmask. The aluminum oxide carbon hybrid hardmask can be used during the fabrication, manufacturing, or preparation of various devices, such as memory devices, logic devices, various microelectronic devices, and other types of devices. A large variety of workpieces or devices containing aluminum oxide carbon hybrid hardmask can be prepared, fabricated, processed, or otherwise made by the methods described and discussed herein.

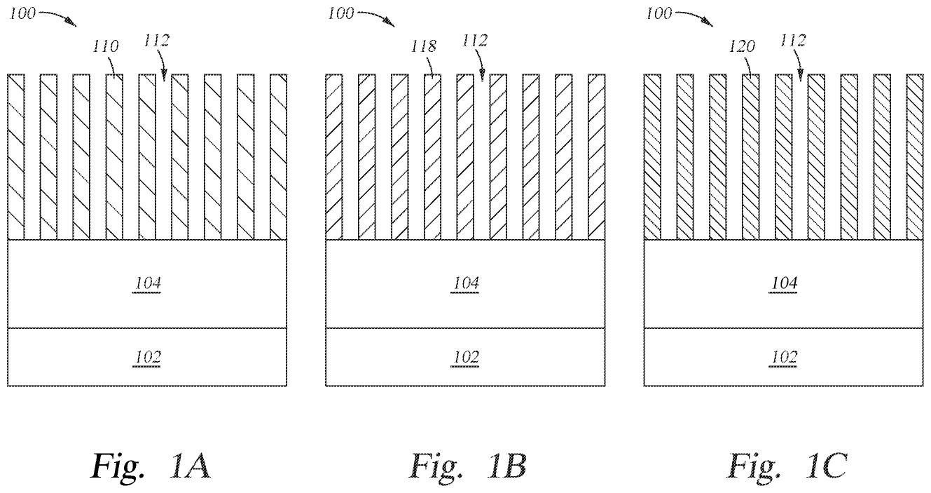

FIGS. 1A-1C depict cross-sectional views of a workpiece 100 at different stages of a treatment process, such as a SIS process, as described and discussed in one or more embodiments herein. The SIS process is used to produce a treated mask or patterned photoresist (PR) layer which is denser and harder than the untreated or original mask patterned PR layer In one or more embodiments, a method of treating a carbon hardmask layer 110 is provided and includes positioning a workpiece 100 within a process region of a processing chamber. The workpiece 100 has a carbon hardmask layer 110 disposed on or over an underlayer 104, as shown in FIG. 1A. The underlayer 104 can be formed, deposited, or otherwise disposed on any other layer (not shown) or a substrate 102, as shown. The method includes treating the carbon hardmask layer 110 by exposing the workpiece 100 to the SIS process to produce an intermediate mask 118, as shown in FIG. 1B and then an aluminum oxide carbon hybrid hardmask 120, as shown in FIG. 1C. The aluminum oxide carbon hybrid hardmask 120 is denser than the carbon hardmask layer 110.

In one or more examples, the SIS process includes one or more infiltration cycles, and each of the infiltration cycles includes sequentially exposing the carbon hardmask layer 110 to an aluminum precursor, infiltrating the carbon hardmask layer 110 with the aluminum precursor via pores contained in the carbon hardmask layer 110, and purging the process region to remove gaseous remnants containing the aluminum precursor. At this stage, the carbon hardmask layer 110 is starting to convert to the intermediate mask 118, which has aluminum incorporated into and on inner surfaces of the carbon hardmask layer 110. The SIS process further includes sequentially exposing the carbon hardmask layer 110 to an oxidizing agent, infiltrating the carbon hardmask layer 110 with the oxidizing agent via the pores contained in the carbon hardmask layer 110 to produce an aluminum oxide coating disposed on inner surfaces of the carbon hardmask layer 110, and purging the process region to remove gaseous remnants containing the oxidizing agent. In some embodiments, the treatment process includes a single infiltration cycle to treat the carbon hardmask layer 110. In other embodiments, the infiltration cycle can be repeated numerous times (e.g., 2 times to about 100 times, or more) to treat the carbon hardmask layer 110.

The substrate 102 can be made of or include one or more materials, such as silicon, silicon oxide, doped silicon, silicon germanium, germanium, gallium arsenide, glass, sapphire, and any other materials, such as metals, metal nitrides, metal alloys, and other conductive or semi-conductive materials, depending on the application. The substrate 102, or surface thereof, can also be made of dielectric materials such as silicon dioxide, silicon nitride, organosilicates, and carbon doped silicon oxide or nitride materials. The substrate 102 can be any geometry, such as round, square, or rectangular. In some examples, the substrate 102 is round and has a diameter of 200 mm, 250 mm, 300 mm, or 450 mm.

The under layer 104 can be or include an oxide layer or a silicon-containing layer, such as silicon oxide, amorphous silicon, a tetraethoxysilane (TEOS) layer, or combinations thereof. The under layer 104 can be formed or otherwise produced by chemical vapor deposition (CVD) or plasma-enhanced CVD (PECVD). In one or more embodiments, the underlayer 104 can be or include metal oxide, metal nitride, silicon oxide, silicon nitride, silicon oxynitride, dopants thereof, or any combination thereof. In some embodiments, the underlayer 104 can be or include a stack disposed on or over the substrate 102. In one or more examples, the stack contains alternating layers of silicon oxide and layers of silicon nitride.

In one or more embodiments, the carbon hardmask layer 110 can be or include carbon, amorphous carbon, spin-on carbon (SOC), dopants thereof, or any combination thereof. The carbon hardmask layer 110 can be formed, deposited, or otherwise produced by one or more processes, such as a thermal chemical vapor deposition (CVD) process, a plasma-enhanced CVD (PE-CVD) process, a flowable CVD (FCVD) process, or a spin-on process. The carbon hardmask layer 110 can be or include a mask or other patterned layer developed, prepared, or otherwise produced by one or multiple processes. In some examples, the carbon hardmask layer 110 is prepared by a lithography process, such as by an extreme ultraviolet (EUV) lithography process. The carbon hardmask layer 110 is porous and can have pores throughout the material including all surfaces of the carbon hardmask layer 110. As shown in FIG. 1A, the carbon hardmask layer 110 has been formed, but remains untreated relative to the SIS process as described and discussed herein.

In one or more embodiments, the carbon hardmask layer 110 has a thickness in a range from about 1 μm to about 20 μm, about 2 μm to about 10 μm, or about 3 μm to about 6 μm. The carbon hardmask layer 110 can be or include a patterned layer which contains a feature pattern of features 112, as shown in FIGS. 1A-1C. The features 112 can have a height which the same or less than the thickness of the carbon hardmask layer 110. As such, the features 112 can have a height in a range from about 1 μm to about 20 μm, about 2 μm to about 10 μm, or about 3 μm to about 6 μm. The features 112 of the patterned layer or the carbon hardmask layer 110 are separated by vias, gaps, or spaces which can have a width of about 5 nm to about 250 nm, about 10 nm to about 150 nm, or about 20 nm to about 100 nm. The features 112 can have an aspect ratio of about 20 to about 500, about 30 to about 300, or about 40 to about 200.

In one or more embodiments, the carbon hardmask layer 110 can be or include carbon-containing materials having polar functional groups, such as one or more C—H groups, one or more C—O groups, one or more C═O groups, or any combination thereof. During the SIS process, the polar functional groups on inner surfaces of the carbon hardmask layer 110 assist with the formation and/or deposition of the aluminum oxide coating via the intermediate mask 118.

In some embodiments, the carbon hardmask layer 110 can contain carbon in a range from about 30 atomic percent (at %), about 40 at %, or about 50 at % to about 60 at %, about 70 at %, or about 80 at %. For example, the carbon hardmask layer 110 can contain carbon in a range from about 30 at % to about 80 at %, about 40 at % to about 80 at %, about 50 at % to about 80 at %, about 60 at % to about 80 at %, about 70 at % to about 80 at %, about 30 at % to about 65 at %, about 40 at % to about 65 at %, about 50 at % to about 65 at %, about 60 at % to about 65 at %, about 30 at % to about 50 at %, about 40 at % to about 50 at %, or about 45 at % to about 50 at %.

The carbon hardmask layer 110 can contain hydrogen in a range from about 10 at %, about 15 at %, about 20 at %, or about 25 at % to about 30 at %, about 35 at %, about 40 at %, about 45 at %, or about 50 at %. For example, the carbon hardmask layer 110 can contain hydrogen in a range from about 10 at % to about 50 at %, about 15 at % to about 50 at %, about 20 at % to about 50 at %, about 25 at % to about 50 at %, about 30 at % to about 50 at %, about 40 at % to about 50 at %, about 10 at % to about 40 at %, about 15 at % to about 40 at %, about 20 at % to about 40 at %, about 25 at % to about 40 at %, about 30 at % to about 40 at %, about 35 at % to about 40 at %, about 10 at % to about 30 at %, about 15 at % to about 30 at %, about 20 at % to about 30 at %, or about 25 at % to about 30 at %.

The carbon hardmask layer 110 can contain oxygen in a range from about 1 at %, about 2 at %, about 3 at %, about 3 at %, about 5 at %, about 6 at %, about 8 at %, or about 10 at % to about 12 at %, about 15 at %, about 16 at %, about 18 at %, or about 20 at %. For example, the carbon hardmask layer 110 can contain oxygen in a range from about 1 at % to about 20 at %, about 2 at % to about 20 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 1 at % to about 15 at %, about 2 at % to about 15 at %, about 5 at % to about 15 at %, about 8 at % to about 15 at %, about 10 at % to about 15 at %, about 12 at % to about 15 at %, about 15 at % to about 15 at %, about 18 at % to about 15 at %, about 1 at % to about 10 at %, about 2 at % to about 10 at %, about 5 at % to about 10 at %, or about 8 at % to about 10 at %.

In one or more examples, the carbon hardmask layer 110 can contain about 30 at % to about 80 at % of carbon, about 10 at % to about 50 at % of hydrogen, and about 10 at % to about 20 at % of oxygen. In some examples, the carbon hardmask layer 110 can contain about 40 at % to about 60 at % of carbon, about 20 at % to about 40 at % of hydrogen, and about 12 at % to about 18 at % of oxygen. In other examples, the carbon hardmask layer 110 can contain about 45 at % to about 55 at % of carbon, about 25 at % to about 35 at % of hydrogen, and about 14 at % to about 16 at % of oxygen.

FIG. 1B depicts the workpiece 100 having the intermediate mask 118, which has as the aluminum precursor or other metal precursor absorbed or otherwise incorporated into and on inner surfaces of the carbon hardmask layer 110. The infiltrated coating of the precursor coats or otherwise is disposed throughout the inner surfaces of the carbon hardmask layer 110. The aluminum or other metal precursor penetrates through the pores contained throughout the carbon hardmask layer 110. The infiltrated coating contains absorbed and/or condensed amounts of the precursor, such as during the first process segment of the SIS process. Thereafter, the process region of the processing chamber can be purged to remove excess or remaining precursor within the process region during the second process segment of the SIS process.

FIG. 1C depicts the workpiece 100 having the aluminum oxide carbon hybrid hardmask 120, which includes the aluminum oxide (or other metal oxide) coating formed within and on the carbon hardmask layer 110. During the third process segment of the SIS process, the infiltrated coating is oxidized by being exposed to an oxidizing agent to form the oxide coating of the aluminum oxide carbon hybrid hardmask 120. Thereafter, the process region of the processing chamber can be purged to remove excess or remaining precursor within the process region during the fourth process segment of the SIS process. The aluminum oxide carbon hybrid hardmask 120 containing the aluminum oxide coating shown in FIG. 1C is denser and harder than the carbon hardmask layer 110 shown in FIG. 1A.

The aluminum oxide carbon hybrid hardmask 120 contains at least aluminum, oxygen, and carbon. In one or more embodiments, the aluminum oxide carbon hybrid hardmask 120 can contain aluminum in a range from about 3 at %, about 4 at %, about 5 at %, about 6 at %, about 8 at %, or about 10 at % to about 12 at %, about 14 at %, about 15 at %, about 16 at %, about 18 at %, about 20 at %, about 22 at %, or about 25 at %. For example, the aluminum oxide carbon hybrid hardmask 120 can contain aluminum in a range from about 3 at % to about 25 at %, about 3 at % to about 20 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 120 can contain oxygen in a range from about 3 at %, about 4 at %, about 5 at %, about 6 at %, about 8 at %, or about 10 at % to about 12 at %, about 15 at %, about 18 at %, about 20 at %, about 22 at %, about 25 at %, about 28 at %, about 30 at %, or about 35 at %. For example, the aluminum oxide carbon hybrid hardmask 120 can contain oxygen in a range from about 3 at % to about 35 at %, about 3 at % to about 30 at %, about 3 at % to about 25 at %, about 3 at % to about 20 at %, about 5 at % to about 35 at %, about 5 at % to about 30 at %, about 5 at % to about 25 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 5 at % to about 30 at %, about 8 at % to about 30 at %, about 10 at % to about 30 at %, about 12 at % to about 30 at %, about 15 at % to about 30 at %, about 18 at % to about 30 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 120 can contain carbon in a range from about 40 at %, about 45 at %, about 50 at %, about 55 at %, about 60 at %, or about 65 at % to about 70 at %, about 75 at %, about 80 at %, about 85 at %, about 90 at %, or about 95 at %. For example, the aluminum oxide carbon hybrid hardmask 120 can contain carbon in a range from about 40 at % to about 90 at %, about 50 at % to about 90 at %, about 60 at % to about 90 at %, about 70 at % to about 90 at %, about 80 at % to about 90 at %, about 40 at % to about 75 at %, about 50 at % to about 75 at %, about 60 at % to about 75 at %, about 70 at % to about 75 at %, about 40 at % to about 60 at %, about 45 at % to about 60 at %, about 50 at % to about 60 at %, or about 55 at % to about 60 at %.

In one or more examples, the aluminum oxide carbon hybrid hardmask 120 can contain about 5 at % to about 20 at % of aluminum, about 5 at % to about 30 at % of oxygen, and about 50 at % to about 90 at % of carbon. In some examples, the aluminum oxide carbon hybrid hardmask 120 can contain about 10 at % to about 20 at % of aluminum, about 10 at % to about 30 at % of oxygen, and about 50 at % to about 80 at % of carbon. In one or more examples, the aluminum oxide carbon hybrid hardmask 120 can contain about 5 at % to about 10 at % of aluminum, about 5 at % to about 20 at % of oxygen, and about 70 at % to about 90 at % of carbon.

The aluminum oxide carbon hybrid hardmask 120 has a thickness in a range from about 1 μm to about 20 μm, about 2 μm to about 10 μm, or about 3 μm to about 6 μm. The aluminum oxide carbon hybrid hardmask 120 can be or include a patterned layer which contains a feature pattern of features 112, as shown in FIG. 1C. The features 112 can have a height which the same or less than the thickness of the aluminum oxide carbon hybrid hardmask 120. As such, the features 112 can have a height in a range from about 1 μm to about 20 μm, about 2 μm to about 10 μm, or about 3 μm to about 6 μm. The features 112 of the patterned layer or the aluminum oxide carbon hybrid hardmask 120 are separated by vias, gaps, or spaces which can have a width of about 5 nm to about 250 nm, about 10 nm to about 150 nm, or about 20 nm to about 100 nm. The features 112 can have an aspect ratio of about 20 to about 500, about 30 to about 300, or about 40 to about 200.

### Sequential Infiltration Synthesis (SIS) Process

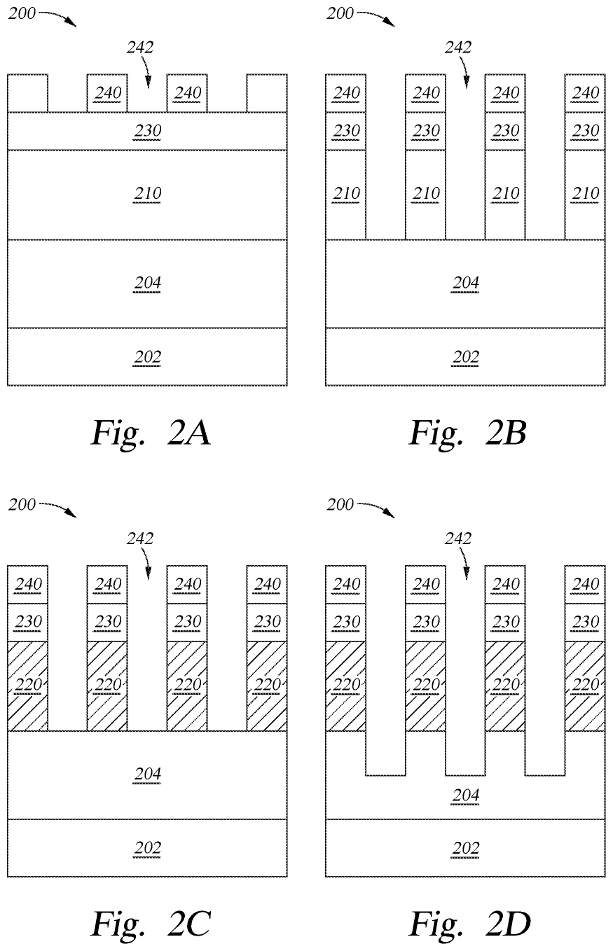

The SIS process described and discussed here for preparing the aluminum oxide carbon hybrid hardmask 120 from the carbon hardmask layer 110, as depicted in FIGS. 1A-1C can also be used to transform any carbon hardmask layer to an aluminum oxide carbon hybrid hardmask, such as those illustrated throughout the FIGS. 2A-4G.

In one or more examples, the SIS process includes one or more infiltration cycles of exposing the carbon hardmask layer 110 to a precursor containing aluminum (e.g., one or more aluminum precursors), infiltrating the carbon hardmask layer 110 with the precursor via pores contained in the carbon hardmask layer 110, purging the process region to remove gaseous remnants containing the precursor, exposing the carbon hardmask layer 110 to an oxidizing agent, infiltrating the carbon hardmask layer 110 with the oxidizing agent via the pores contained in the carbon hardmask layer 110 to produce aluminum oxide coating disposed on inner surfaces of the carbon hardmask layer 110 and purging the process region to remove gaseous remnants containing the oxidizing agent.

Each of the infiltration cycles of the SIS process include a first process segment of exposing and infiltrating by a precursor, a second process segment of purging the process region to remove remaining gaseous precursor, a third process segment of exposing and infiltrating by an oxidizing agent, and a fourth process segment of purging the process region to remove remaining gaseous precursor. The process segments of the infiltration cycle are sequentially repeated during each of the infiltration cycles. One or more carrier gases can be flowed into the process region along with the precursor and/or the oxidizing agent during the first and third process segments, respectively, of the SIS process. One or more purge gases can be flowed into the process region which is also being evacuated during the second and fourth process segments of the SIS process. The carrier gas and the purge gas can be the same composition or different compositions. Exemplary carrier gases and/or purge gases can be or include argon, helium, neon, nitrogen (N₂), hydrogen (H₂), or any combination thereof.

The process region of the processing chamber is the internal volume within the processing chamber. The process region and/or the internal volume of the processing chamber are maintained at and/or adjusted to one or more pressures below atmospheric or ambient pressure (e.g., less than 760 Torr) during the SIS process. The pressure of the process region and/or the internal volume of the processing chamber is at about 0.01 Torr, about 0.1 Torr, about 1 Torr, about 1 Torr, about 5 Torr, about 10 Torr, about 15 Torr, about 20 Torr, about 25 Torr, about 35 Torr, or about 50 Torr to about 80 Torr, about 100 Torr, about 150 Torr, about 200 Torr, about 250 Torr, about 300 Torr, about 350 Torr, about 400 Torr, about 450 Torr, about 500 Torr, or about 600 Torr during the SIS process. For example, the pressure of the process region and/or the internal volume of the processing chamber is at about 0.01 Torr to about 600 Torr, about 0.01 Torr to about 500 Torr, about 0.01 Torr to about 400 Torr, about 0.01 Torr to about 350 Torr, about 0.01 Torr to about 300 Torr, about 0.01 Torr to about 250 Torr, about 0.01 Torr to about 200 Torr, about 0.01 Torr to about 150 Torr, about 0.01 Torr to about 100 Torr, about 0.01 Torr to about 50 Torr, about 0.1 Torr to about 600 Torr, about 0.1 Torr to about 500 Torr, about 0.1 Torr to about 400 Torr, about 0.1 Torr to about 350 Torr, about 0.1 Torr to about 300 Torr, about 0.1 Torr to about 250 Torr, about 0.1 Torr to about 200 Torr, about 0.1 Torr to about 150 Torr, about 0.1 Torr to about 100 Torr, about 0.1 Torr to about 50 Torr, about 1 Torr to about 600 Torr, about 1 Torr to about 500 Torr, about 1 Torr to about 400 Torr, about 1 Torr to about 350 Torr, about 1 Torr to about 300 Torr, about 1 Torr to about 250 Torr, about 1 Torr to about 200 Torr, about 1 Torr to about 150 Torr, about 1 Torr to about 100 Torr, about 1 Torr to about 50 Torr, about 10 Torr to about 600 Torr, about 10 Torr to about 500 Torr, about 10 Torr to about 400 Torr, about 10 Torr to about 350 Torr, about 10 Torr to about 300 Torr, about 10 Torr to about 250 Torr, about 10 Torr to about 200 Torr, about 10 Torr to about 150 Torr, about 10 Torr to about 100 Torr, about 10 Torr to about 50 Torr, about 15 Torr to about 600 Torr, about 15 Torr to about 500 Torr, about 15 Torr to about 400 Torr, about 15 Torr to about 350 Torr, about 15 Torr to about 300 Torr, about 15 Torr to about 250 Torr, about 15 Torr to about 200 Torr, about 15 Torr to about 150 Torr, about 15 Torr to about 100 Torr, about 15 Torr to about 50 Torr, about 50 Torr to about 600 Torr, about 50 Torr to about 500 Torr, about 50 Torr to about 400 Torr, about 50 Torr to about 350 Torr, about 50 Torr to about 300 Torr, about 50 Torr to about 250 Torr, about 50 Torr to about 200 Torr, about 50 Torr to about 150 Torr, about 50 Torr to about 100 Torr, about 100 Torr to about 600 Torr, about 100 Torr to about 500 Torr, about 100 Torr to about 400 Torr, about 100 Torr to about 350 Torr, about 100 Torr to about 300 Torr, about 100 Torr to about 250 Torr, about 100 Torr to about 200 Torr, or about 100 Torr to about 150 Torr during the SIS process. In one or more examples, the pressure of the process region and/or the internal volume of the processing chamber is at about 0.01 Torr to about 250 Torr during the SIS process or about 0.1 Torr to about 50 Torr during the SIS process.

Each of the first process segment and the third process segment of the infiltration cycle can independently last about 20 seconds, about 30 seconds, about 35 seconds, about 40 seconds, or about 45 seconds to about 50 seconds, about 60 seconds, about 70 seconds, about 80 seconds, about 90 seconds, about 100 seconds, about 2 minutes, about 2.5 minutes, about 3 minutes, about 4 minutes, about 5 minutes, about 6 minutes, about 8 minutes, about 10 minutes, about 12 minutes, about 15 minutes, about 18 minutes, or about 20 minutes during the SIS process. For example, each of the first process segment and the third process segment of the infiltration cycle can independently last about 20 seconds to about 20 minutes, about 20 seconds to about 15 minutes, about 20 seconds to about 12 minutes, about 20 seconds to about 10 minutes, about 20 seconds to about 8 minutes, about 20 seconds to about 6 minutes, about 20 seconds to about 5 minutes, about 20 seconds to about 4 minutes, about 20 seconds to about 3 minutes, about 20 seconds to about 2.5 minutes, about 20 seconds to about 2 minutes, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 40 seconds to about 5 minutes, about 40 seconds to about 4 minutes, about 40 seconds to about 3 minutes, about 40 seconds to about 2.5 minutes, about 40 seconds to about 2 minutes, about 40 seconds to about 100 seconds, about 40 seconds to about 90 seconds, about 40 seconds to about 75 seconds, about 40 seconds to about 60 seconds, about 60 seconds to about 20 minutes, about 60 seconds to about 15 minutes, about 60 seconds to about 12 minutes, about 60 seconds to about 10 minutes, about 60 seconds to about 8 minutes, about 60 seconds to about 6 minutes, about 60 seconds to about 5 minutes, about 60 seconds to about 4 minutes, about 60 seconds to about 3 minutes, about 60 seconds to about 2.5 minutes, about 60 seconds to about 2 minutes, about 60 seconds to about 100 seconds, about 60 seconds to about 90 seconds, or about 60 seconds to about 75 seconds during the SIS process.

In one or more examples, the carbon hardmask layer 110 is exposed to the aluminum precursor for about 1 minute to about 10 minutes while infiltrating the carbon hardmask layer 110 with the aluminum precursor during the first process segment of each infiltration cycle. In some examples, the carbon hardmask layer 110 is exposed to the oxidizing agent for about 1 minute to about 10 minutes while infiltrating the carbon hardmask layer 110 with the oxidizing agent during the third process segment of each infiltration cycle.

Each of the second process segment and the fourth process segment of the infiltration cycle can independently last about 20 seconds, about 30 seconds, about 35 seconds, about 40 seconds, about 45 seconds, about 50 seconds, about 60 seconds, about 70 seconds, about 80 seconds, or about 90 seconds, about 100 seconds, about 2 minutes, about 2.5 minutes, about 3 minutes, about 4 minutes, about 5 minutes, about 6 minutes, about 8 minutes, about 10 minutes, about 12 minutes, about 15 minutes, about 20 minutes, about 25 minutes, or about 30 minutes during the SIS process. For example, each of the second process segment and the fourth process segment of the infiltration cycle can independently last about 20 seconds to about 30 minutes, about 20 seconds to about 25 minutes, about 20 seconds to about 20 minutes, about 20 seconds to about 15 minutes, about 20 seconds to about 12 minutes, about 20 seconds to about 10 minutes, about 20 seconds to about 8 minutes, about 20 seconds to about 6 minutes, about 20 seconds to about 5 minutes, about 20 seconds to about 4 minutes, about 20 seconds to about 3 minutes, about 20 seconds to about 2.5 minutes, about 20 seconds to about 2 minutes, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 40 seconds to about 5 minutes, about 40 seconds to about 4 minutes, about 40 seconds to about 3 minutes, about 40 seconds to about 2.5 minutes, about 40 seconds to about 2 minutes, about 40 seconds to about 100 seconds, about 40 seconds to about 90 seconds, about 40 seconds to about 75 seconds, about 40 seconds to about 60 seconds, about 60 seconds to about 20 minutes, about 60 seconds to about 15 minutes, about 60 seconds to about 12 minutes, about 60 seconds to about 10 minutes, about 60 seconds to about 8 minutes, about 60 seconds to about 6 minutes, about 60 seconds to about 5 minutes, about 60 seconds to about 4 minutes, about 60 seconds to about 3 minutes, about 60 seconds to about 2.5 minutes, about 60 seconds to about 2 minutes, about 60 seconds to about 100 seconds, about 60 seconds to about 90 seconds, or about 60 seconds to about 75 seconds during the SIS process.

In one or more examples, the carbon hardmask layer 110 is exposed to a purge gas for about 1 minute to about 30 minutes while purging the process region to remove the gaseous remnants containing the aluminum precursor during the second process segment of each infiltration cycle. In other examples, the carbon hardmask layer 110 is exposed to a purge gas for about 1 minute to about 30 minutes while purging the process region to remove the gaseous remnants containing the oxidizing agent during the fourth process segment of each infiltration cycle.

The infiltration cycle can be conducted once, twice, or multiple times during the SIS process. The process segments of the infiltration cycle are sequentially repeated during each of the infiltration cycles. In some examples, the infiltration cycle is repeated 2 times, 3 times, 4 times, or 5 times to 6 times, 7 times, 8 times, 9 times, about 10 times, about 12 times, about 15 times, about 20 times, about 30 times, about 40 times, about 50 times, about 60 times, about 80 times, about 100 times, or more during the SIS process. For example, the infiltration cycle is repeated 2 times to about 100 times, 2 times to about 80 times, 2 times to about 50 times, 2 times to about 20 times, 2 times to about 15 times, 2 times to about 10 times, 2 times to 8 times, 2 times to 5 times during the SIS process. In one or more examples, the SIS process includes 1 cycle to about 100 cycles, 5 cycles to about 80 cycles, about 10 cycles to about 50 cycles, or about 20 cycles to about 40 cycles of the infiltration cycle.

The precursor exposed to the carbon hardmask layer 110 can be one or more aluminum precursors or other metal precursors. The oxidizing agent can be or include any compound or reagent which will oxidize the aluminum precursor to produce aluminum oxide or another metal precursor to produce the respective metal oxide. The oxidizing agent can be or include water, ozone, oxygen plasma, oxygen radicals, oxygen (O₂), hydrogen peroxide, or any combination thereof.

In one or more embodiments, the precursor is or includes one or more aluminum precursors and the oxide coating formed within the carbon hardmask layer 110 is or includes aluminum oxide. The aluminum precursor can be or include one or more alkylaluminum compounds, one or more alkoxyaluminum compounds, one or more aluminum halide compounds, aluminum hydrides, or any combination thereof. In some examples, the aluminum precursor is or contains trimethyl aluminum, triethyl aluminum, tripropyl aluminum, tributyl aluminum, dimethyl aluminum, diethyl aluminum, dipropyl aluminum, dibutyl aluminum, complexes thereof, or combinations thereof.

In one or more examples, the aluminum precursor is or contains one or more alkylaluminum compounds (e.g., trimethylaluminum) and the oxidizing agent is or includes water. In other examples, the aluminum precursor is or contains one or more alkoxyaluminum compounds and the oxidizing agent is or contains ozone or oxygen plasma.

FIGS. 2A-2D depict cross-sectional views of a workpiece 200 at different stages of a process for preparing or otherwise forming a device, as described and discussed in one or more embodiments herein. The device can be or include a memory device, a logic device, a microelectronic device, and/or other devices. In one of more embodiments, methods for forming a device is provided and includes positioning the workpiece 200 within a process region of a processing chamber. The workpiece 200 contains a carbon hardmask layer 210 disposed on or over an underlayer 204, a silicon-containing hardmask 230 disposed on or over the carbon hardmask layer 210, and a patterned photoresist (PR) layer 240 having a feature pattern of features 242 disposed on the silicon-containing hardmask 230. The method also includes etching the silicon-containing hardmask 230 and the carbon hardmask layer 210 to each have the features 242 of the patterned PR layer 240, treating the carbon hardmask layer 210 by exposing the workpiece 200 to a SIS process to produce an aluminum oxide carbon hybrid hardmask 220, and then etching the underlayer 204 to have the features 242 of the patterned PR layer 240.

The underlayer 204 can be or include metal oxide, metal nitride, silicon oxide, silicon nitride, silicon oxynitride, dopants thereof, or any combination thereof. The underlayer 204 can be or include a stack disposed on or over a substrate 202. In one or more examples, the stack contains alternating layers of silicon oxide and layers of silicon nitride. The substrate 202 can be or include any type of substrate including the substrate 102 described and discussed above. In some examples, the underlayer 204 can be or include any type of one or more layers including the under layer 104 described and discussed above.

The patterned PR layer 240 can be deposited, formed, positioned, or otherwise disposed on the silicon-containing hardmask 230, as depicted in FIG. 2A. In one or more embodiments, the patterned PR layer 240 can be produced or otherwise formed by an extreme ultraviolet (EUV) lithography process or a deep ultraviolet (DUV) lithography process. In one or more examples, the patterned PR layer 240 can be or include an EUV stack which includes a PR layer under a bottom ARC (BARC) layer to provide a PR/BARC stack. In other examples, the patterned PR layer 240 can be or include a DUV stack which includes a PR layer under a BARC layer under a dielectric ARC (DARC) layer to provide a PR/BARC/DARC stack.

In some embodiments, the features 242 are etched completely through the thickness of the silicon-containing hardmask 230, as depicted in FIG. 2B. The silicon-containing hardmask 230 can be or include silicon oxide, silicon nitride, silicon oxynitride, dopants thereof, or any combination thereof. In one or more examples, the silicon-containing hardmask 230 can be etched or otherwise removed by exposing the silicon-containing hardmask 230 to one or more fluorocarbon etchants and one or more process gases. The fluorocarbon etchant can be or include tetrafluoromethane, trifluoromethane, difluoromethane, monofluoromethane, octafluorocyclobutane, hexafluoro-1,3-butadiene, or any combination thereof. The process gas can be or include argon, helium, nitrogen (N₂), oxygen (O₂), or any combination thereof.

In some examples, the features 242 are etched at least partially or completely through a thickness of the carbon hardmask layer 210, as depicted in FIG. 2B. The carbon hardmask layer 210 can be or include any type of carbon hardmask including the carbon hardmask 110 described and discussed above. In one or more examples, the carbon hardmask layer 210 can be etched or otherwise removed by exposing the carbon hardmask layer 210 to one or more etchant gases and one or more passivation gases. The etchant gas can be or include argon, oxygen, or a combination thereof, and the passivation gas can be or include methane, sulfur dioxide, carbonyl sulfide, or any combination thereof.

FIGS. 2B-2C depict the treatment or transition of the carbon hardmask layer 210 (FIG. 2B) to produce the aluminum oxide carbon hybrid hardmask 220 (FIG. 2C) via the SIS process. The SIS process is selective to the carbon hardmask layer 210 while being unreactive or substantially unreactive to the other exposed surfaces and layers, such as the underlayer 204, the silicon-containing hardmask 230, and the patterned PR layer 240, on the workpiece 200. The aluminum oxide carbon hybrid hardmask 220 is denser than the carbon hardmask layer 210. The aluminum oxide carbon hybrid hardmask 220 can have the compositions and properties as the aluminum oxide carbon hybrid hardmask 120 described and discussed above.

In some examples, the features 242 are etched at least partially or completely through a thickness of the underlayer 204. As shown in FIG. 2D, the features 242 are only partially etched into the thickness of the underlayer 204. The underlayer 204 can be partially etched by exposing the underlayer 204 to one or more fluorocarbon etchants and one or more process gases. The fluorocarbon etchant can be or include tetrafluoromethane, trifluoromethane, difluoromethane, monofluoromethane, octafluorocyclobutane, hexafluoro-1,3-butadiene, or any combination thereof. The process gas can be or include argon, helium, nitrogen (N₂), oxygen (O₂), or any combination thereof.

The aluminum oxide carbon hybrid hardmask 220 contains at least aluminum, oxygen, and carbon. In one or more embodiments, the aluminum oxide carbon hybrid hardmask 220 can contain aluminum in a range from about 3 at %, about 4 at %, about 5 at %, about 6 at %, about 8 at %, or about 10 at % to about 12 at %, about 14 at %, about 15 at %, about 16 at %, about 18 at %, about 20 at %, about 22 at %, or about 25 at %. For example, the aluminum oxide carbon hybrid hardmask 220 can contain aluminum in a range from about 3 at % to about 25 at %, about 3 at % to about 20 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 220 can contain oxygen in a range from about 3 at %, about 4 at %, about 5 at %, about 6 at %, about 8 at %, or about 10 at % to about 12 at %, about 15 at %, about 18 at %, about 20 at %, about 22 at %, about 25 at %, about 28 at %, about 30 at %, or about 35 at %. For example, the aluminum oxide carbon hybrid hardmask 220 can contain oxygen in a range from about 3 at % to about 35 at %, about 3 at % to about 30 at %, about 3 at % to about 25 at %, about 3 at % to about 20 at %, about 5 at % to about 35 at %, about 5 at % to about 30 at %, about 5 at % to about 25 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 5 at % to about 30 at %, about 8 at % to about 30 at %, about 10 at % to about 30 at %, about 12 at % to about 30 at %, about 15 at % to about 30 at %, about 18 at % to about 30 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 220 can contain carbon in a range from about 40 at %, about 45 at %, about 50 at %, about 55 at %, about 60 at %, or about 65 at % to about 70 at %, about 75 at %, about 80 at %, about 85 at %, about 90 at %, or about 95 at %. For example, the aluminum oxide carbon hybrid hardmask 220 can contain carbon in a range from about 40 at % to about 90 at %, about 50 at % to about 90 at %, about 60 at % to about 90 at %, about 70 at % to about 90 at %, about 80 at % to about 90 at %, about 40 at % to about 75 at %, about 50 at % to about 75 at %, about 60 at % to about 75 at %, about 70 at % to about 75 at %, about 40 at % to about 60 at %, about 45 at % to about 60 at %, about 50 at % to about 60 at %, or about 55 at % to about 60 at %.

In one or more examples, the aluminum oxide carbon hybrid hardmask 220 can contain about 5 at % to about 20 at % of aluminum, about 5 at % to about 30 at % of oxygen, and about 50 at % to about 90 at % of carbon. In some examples, the aluminum oxide carbon hybrid hardmask 220 can contain about 10 at % to about 20 at % of aluminum, about 10 at % to about 30 at % of oxygen, and about 50 at % to about 80 at % of carbon. In one or more examples, the aluminum oxide carbon hybrid hardmask 220 can contain about 5 at % to about 10 at % of aluminum, about 5 at % to about 20 at % of oxygen, and about 70 at % to about 90 at % of carbon.

The aluminum oxide carbon hybrid hardmask 220 has a thickness in a range from about 1 μm to about 20 μm, about 2 μm to about 10 μm, or about 3 μm to about 6 μm. The aluminum oxide carbon hybrid hardmask 220 can be or include a patterned layer which contains a feature pattern of features 242, as shown in FIG. 2D. The feature pattern or the features 242 can have a height which the same or less than the thickness of the aluminum oxide carbon hybrid hardmask 220. As such, the feature pattern or the features 242 can have a height in a range from about 1 μm to about 20 μm, about 2 μm to about 10 μm, or about 3 μm to about 6 μm. The feature pattern or the features 242 of the patterned layer or the aluminum oxide carbon hybrid hardmask 220 are separated by vias, gaps, or spaces which can have a width of about 5 nm to about 250 nm, about 10 nm to about 150 nm, or about 20 nm to about 100 nm. The feature pattern or the features 242 can have an aspect ratio of about 20 to about 500, about 30 to about 300, or about 40 to about 200.

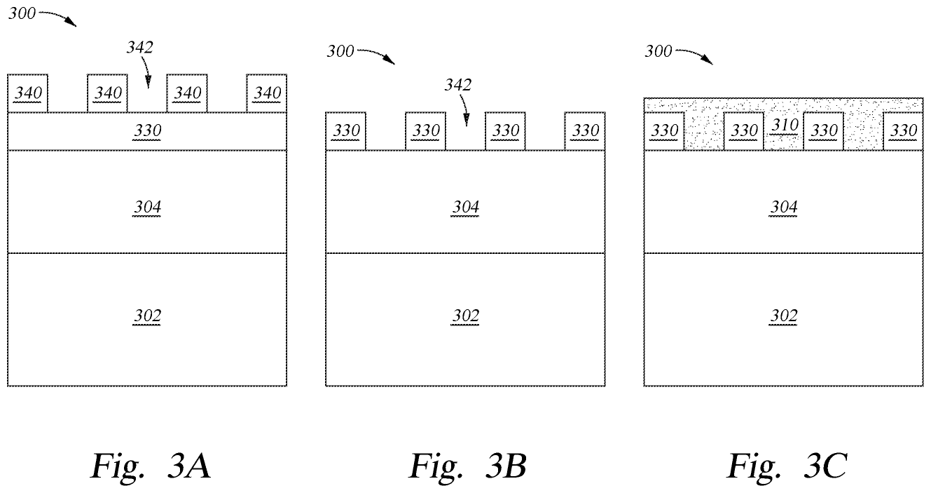

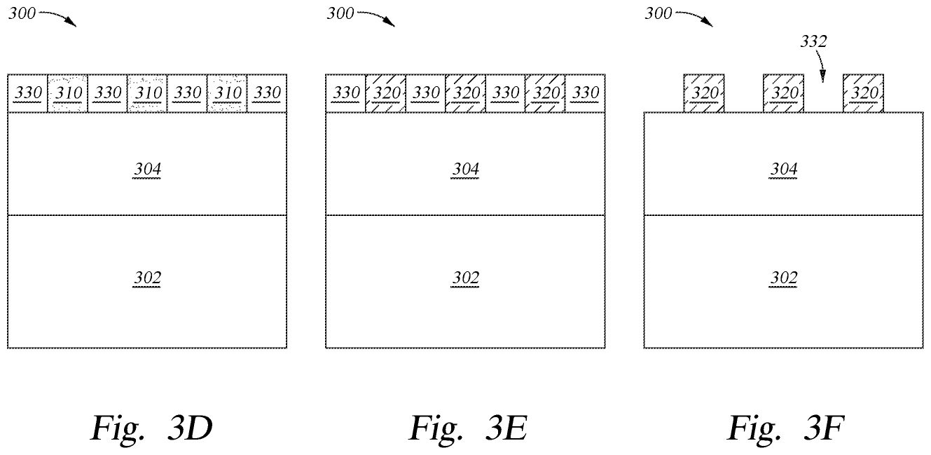

FIGS. 3A-3F depict cross-sectional views of a workpiece 300 at different stages of a process for preparing or otherwise forming a device, as described and discussed in one or more embodiments herein. The device can be or include a memory device, a logic device, a microelectronic device, and/or other devices. In one or more embodiments, method for forming or otherwise preparing a device is provided and includes positioning the workpiece 300 within a process region of a processing chamber, where the workpiece 300 contains a metal or metal nitride layer 304 disposed on or over a substrate 302, a silicon-containing hardmask 330 disposed on or over the metal or metal nitride layer 304, and a patterned photoresist (PR) layer 340 having a feature pattern of features 342 disposed on the silicon-containing hardmask 330. The method further includes etching the silicon-containing hardmask 330 to have the feature pattern of features 342 of the patterned PR layer 340, removing the patterned PR layer 340 from the silicon-containing hardmask 330, and depositing a carbon hardmask layer 310 at least into the features 342 of the patterned PR layer 340. The method also includes treating the carbon hardmask layer 310 by exposing the workpiece 300 to a SIS process to produce an aluminum oxide carbon hybrid hardmask 320 which is denser than the carbon hardmask layer 310, and then etching the silicon-containing hardmask 330 to produce a reverse pattern 332 within the aluminum oxide carbon hybrid hardmask 320.

The patterned PR layer 340 can be deposited, formed, positioned, or otherwise disposed on the silicon-containing hardmask 330, as depicted in FIG. 3A. In one or more embodiments, the patterned PR layer 340 can be produced or otherwise formed by an extreme ultraviolet (EUV) lithography process or a deep ultraviolet (DUV) lithography process. In one or more examples, the patterned PR layer 340 can be or include an EUV stack which includes a PR layer under a bottom ARC (BARC) layer to provide a PR/BARC stack. In other examples, the patterned PR layer 340 can be or include a DUV stack which includes a PR layer under a BARC layer under a dielectric ARC (DARC) layer to provide a PR/BARC/DARC stack.

The metal or metal nitride layer 304 can be or include metal oxide, metal nitride, silicon oxide, silicon nitride, silicon oxynitride, dopants thereof, or any combination thereof. The metal or metal nitride layer 304 can be or include a stack disposed on or over a substrate 302. In one or more examples, the stack contains alternating layers of silicon oxide and layers of silicon nitride. The substrate 302 can be or include any type of substrate including the substrate 102 described and discussed above.

In some examples, the metal or metal nitride layer 304 can be or include one or more metal layers. In one or more examples, the metal layer can be or include metallic titanium, metallic tantalum, metallic tungsten, alloys thereof of any combination thereof. In other examples, the metal or metal nitride layer 304 can be or include a metal nitride layer, and the metal nitride layer can be or include titanium nitride, tantalum nitride, tungsten nitride, alloys thereof of any combination thereof. In some examples, the metal or metal nitride layer 304 can be or include any type of one or more layers including the under layer 104 described and discussed above.

In some embodiments, the features 342 are etched completely through the thickness of the silicon-containing hardmask 330, as depicted in FIG. 3B. Thereafter, the patterned PR layer 340 can be removed from the workpiece 300. The silicon-containing hardmask 330 can be or include silicon oxide, silicon nitride, silicon oxynitride, dopants thereof, or any combination thereof. In one or more examples, the silicon-containing hardmask 330 can be or include any type of hardmask including the silicon-containing hardmask 230 described and discussed above. In some examples, the silicon-containing hardmask 330 can be etched or otherwise removed by exposing the silicon-containing hardmask 330 to one or more fluorocarbon etchants and one or more process gases. The fluorocarbon etchant can be or include tetrafluoromethane, trifluoromethane, difluoromethane, monofluoromethane, octafluorocyclobutane, hexafluoro-1,3-butadiene, or any combination thereof. The process gas can be or include argon, helium, nitrogen (N₂), oxygen (O₂), or any combination thereof.

In one or more embodiments, the patterned PR layer 340 can be from the silicon-containing hardmask 330 includes exposing the patterned PR layer 340 to an etching process. In some examples, the etching process includes exposing the patterned PR layer 340 to a combination of one or more halogen-containing compounds and at least one of oxygen (O₂), argon, helium, or combination thereof. The halogen-containing compound can be or include chloride (Cl₂), hydrogen bromide (HBr), or any combination thereof. In other embodiments, the patterned PR layer 340 can be removed from the silicon-containing hardmask 330 by exposing the patterned PR layer 340 to a polishing process. The polishing process can be a chemical mechanical polishing (CMP) process.

A carbon hardmask layer 310 can be deposited or otherwise formed onto upper surfaces of the patterned PR layer 340 while depositing the carbon hardmask layer 310 into the feature pattern of features 342 of the patterned PR layer 340, as depicted in FIG. 3C. The carbon hardmask layer 310 can have the compositions and properties and be deposited or otherwise formed by the same processes as the carbon hardmask layer 110 described and discussed above.

The carbon hardmask layer 310 can be removed from the upper surfaces of the patterned PR layer 340 before treating the carbon hardmask layer 310 to the SIS process, as depicted in FIG. 3D. In one or more examples, the carbon hardmask layer 310 is removed from the upper surfaces of the patterned PR layer 340 includes a polishing process (e.g., CMP).

FIGS. 3D-3E depict the treatment or transition of the carbon hardmask layer 310 (FIG. 3D) to produce the aluminum oxide carbon hybrid hardmask 320 (FIG. 3E) via the SIS process. The SIS process is selective to the carbon hardmask layer 310 while being unreactive or substantially unreactive to the other exposed surfaces and layers, such as the metal or metal nitride layer 304 and the silicon-containing hardmask 330 on the workpiece 300. The aluminum oxide carbon hybrid hardmask 320 is denser than the carbon hardmask layer 310. The aluminum oxide carbon hybrid hardmask 320 can have the compositions and properties as the aluminum oxide carbon hybrid hardmask 120 described and discussed above.

In one or more embodiments, the silicon-containing hardmask 330 can be etched or otherwise removed to produce the reverse pattern 332 within the aluminum oxide carbon hybrid hardmask 320, as depicted in FIG. 3F. In one or more examples, the silicon-containing hardmask 330 can be etched by exposing the workpiece 300 to an inductively coupled plasma (ICP) to remove the silicon-containing hardmask 330 while maintaining the aluminum oxide carbon hybrid hardmask 320 on the metal or metal nitride layer 304. In some examples, the ICP contains or can be formed from a mixture of oxygen (O₂) and argon.

In other embodiments, the silicon-containing hardmask 330 can be etched or otherwise removed etched to produce the reverse pattern 332 within the aluminum oxide carbon hybrid hardmask 320 by other processes. The workpiece 300 can be exposed to a selective removal process or a wet etch process to remove the silicon-containing hardmask 330 while maintaining the aluminum oxide carbon hybrid hardmask 320 on the metal or metal nitride layer 304.

The aluminum oxide carbon hybrid hardmask 320 contains at least aluminum, oxygen, and carbon. In one or more embodiments, the aluminum oxide carbon hybrid hardmask 320 can contain aluminum in a range from about 3 at %, about 4 at %, about 5 at %, about 6 at %, about 8 at %, or about 10 at % to about 12 at %, about 14 at %, about 15 at %, about 16 at %, about 18 at %, about 20 at %, about 22 at %, or about 25 at %. For example, the aluminum oxide carbon hybrid hardmask 320 can contain aluminum in a range from about 3 at % to about 25 at %, about 3 at % to about 20 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 320 can contain oxygen in a range from about 3 at %, about 4 at %, about 5 at %, about 6 at %, about 8 at %, or about 10 at % to about 12 at %, about 15 at %, about 18 at %, about 20 at %, about 22 at %, about 25 at %, about 28 at %, about 30 at %, or about 35 at %. For example, the aluminum oxide carbon hybrid hardmask 320 can contain oxygen in a range from about 3 at % to about 35 at %, about 3 at % to about 30 at %, about 3 at % to about 25 at %, about 3 at % to about 20 at %, about 5 at % to about 35 at %, about 5 at % to about 30 at %, about 5 at % to about 25 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 5 at % to about 30 at %, about 8 at % to about 30 at %, about 10 at % to about 30 at %, about 12 at % to about 30 at %, about 15 at % to about 30 at %, about 18 at % to about 30 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 320 can contain carbon in a range from about 40 at %, about 45 at %, about 50 at %, about 55 at %, about 60 at %, or about 65 at % to about 70 at %, about 75 at %, about 80 at %, about 85 at %, about 90 at %, or about 95 at %. For example, the aluminum oxide carbon hybrid hardmask 320 can contain carbon in a range from about 40 at % to about 90 at %, about 50 at % to about 90 at %, about 60 at % to about 90 at %, about 70 at % to about 90 at %, about 80 at % to about 90 at %, about 40 at % to about 75 at %, about 50 at % to about 75 at %, about 60 at % to about 75 at %, about 70 at % to about 75 at %, about 40 at % to about 60 at %, about 45 at % to about 60 at %, about 50 at % to about 60 at %, or about 55 at % to about 60 at %.

In one or more examples, the aluminum oxide carbon hybrid hardmask 320 can contain about 5 at % to about 20 at % of aluminum, about 5 at % to about 30 at % of oxygen, and about 50 at % to about 90 at % of carbon. In some examples, the aluminum oxide carbon hybrid hardmask 320 can contain about 10 at % to about 20 at % of aluminum, about 10 at % to about 30 at % of oxygen, and about 50 at % to about 80 at % of carbon. In one or more examples, the aluminum oxide carbon hybrid hardmask 320 can contain about 5 at % to about 10 at % of aluminum, about 5 at % to about 20 at % of oxygen, and about 70 at % to about 90 at % of carbon.

The aluminum oxide carbon hybrid hardmask 320 has a thickness in a range from about 1 μm to about 20 μm, about 2 μm to about 10 μm, or about 3 μm to about 6 μm. The aluminum oxide carbon hybrid hardmask 320 can be or include a patterned layer which contains the feature pattern of features 342, as shown in FIG. 3F. The feature pattern or the features 342 can have a height which the same or less than the thickness of the aluminum oxide carbon hybrid hardmask 320. As such, the feature pattern or the features 342 can have a height in a range from about 1 μm to about 20 μm, about 2 μm to about 10 μm, or about 3 μm to about 6 μm. The feature pattern or the features 342 of the patterned layer or the aluminum oxide carbon hybrid hardmask 320 are separated by vias, gaps, or spaces which can have a width of about 5 nm to about 250 nm, about 10 nm to about 150 nm, or about 20 nm to about 100 nm. The feature pattern or the features 342 can have an aspect ratio of about 20 to about 500, about 30 to about 300, or about 40 to about 200.

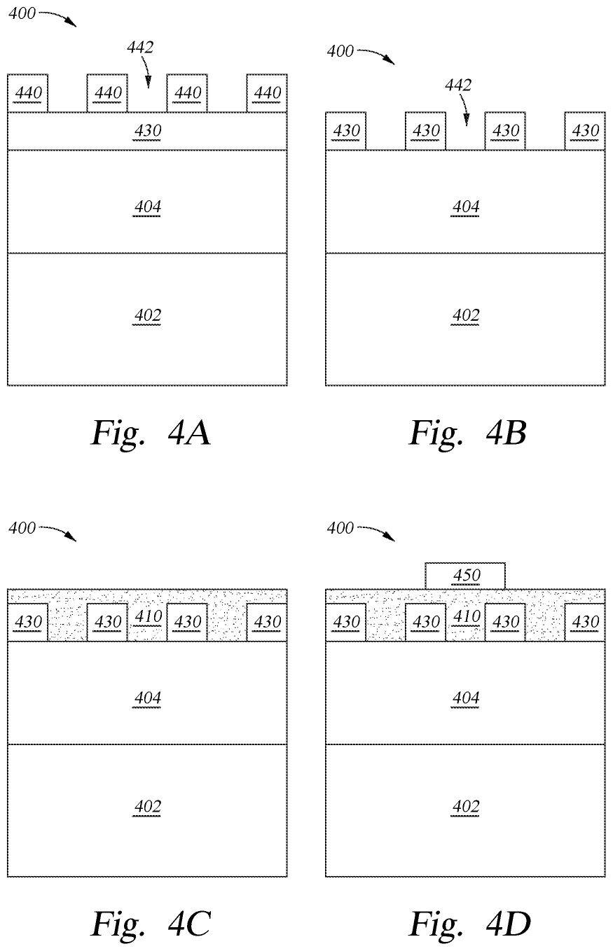

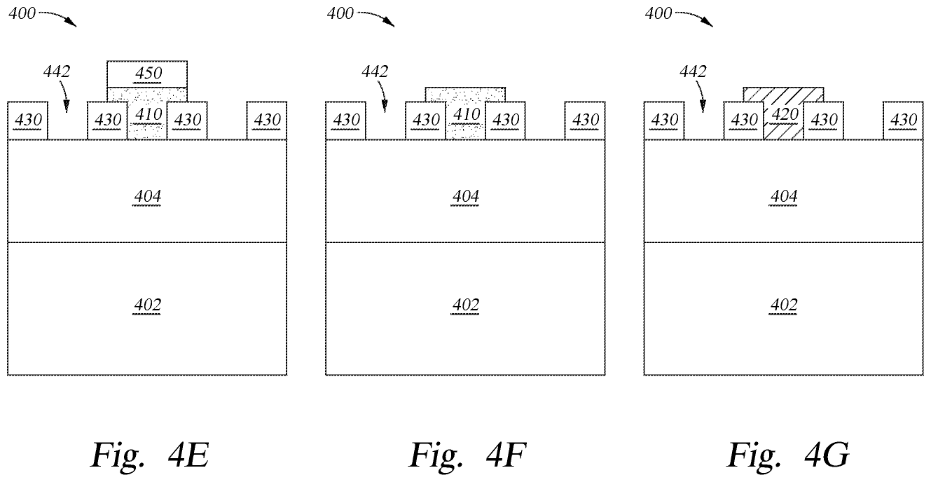

FIGS. 4A-4G depict cross-sectional views of a workpiece 400 at different stages of a process for preparing or otherwise forming a device, as described and discussed in one or more embodiments herein. The device can be or include a memory device, a logic device, a microelectronic device, and/or other devices. In one or more embodiments, method for forming or otherwise producing a device is provided and includes positioning the workpiece 400 within a process region of a processing chamber, where the workpiece 400 contains a metal or metal nitride layer 404 disposed on or over a substrate 402, a silicon-containing hardmask 430 disposed on or over the metal or metal nitride layer 404, and a patterned photoresist (PR) layer 440 having a feature pattern of features 442 disposed on the silicon-containing hardmask 430. The method also includes etching the silicon-containing hardmask 430 to have the feature pattern of features 442 of the patterned PR layer 440, removing the patterned PR layer 440 from the silicon-containing hardmask 430, and depositing a carbon hardmask layer 410 into the features 442 of the patterned PR layer 440 and onto an upper surface of the patterned PR layer 440. The method further includes depositing a photoresist-antireflective coating (PR-ARC) layer 450 on a first portion of the carbon hardmask layer 410 while leaving exposed a second portion of the carbon hardmask layer 410. Also, the method includes etching the second portion of the carbon hardmask layer 410 while maintaining the PR-ARC layer 450 and the first portion of the carbon hardmask layer 410 on the workpiece 400 during a first mask etch process and etching the PR-ARC layer 450 while maintaining the first portion of the carbon hardmask layer 410 on the workpiece 400 during a second mask etch process. The method further includes treating the first portion of the carbon hardmask layer 410 by exposing the workpiece 400 to a SIS process to produce an aluminum oxide carbon hybrid hardmask 420 which is denser than the carbon hardmask layer 410.

The patterned PR layer 440 can be deposited, formed, positioned, or otherwise disposed on the silicon-containing hardmask 430, as depicted in FIG. 4A. In one or more embodiments, the patterned PR layer 440 can be produced or otherwise formed by an extreme ultraviolet (EUV) lithography process or a deep ultraviolet (DUV) lithography process. In one or more examples, the patterned PR layer 440 can be or include an EUV stack which includes a PR layer under a bottom ARC (BARC) layer to provide a PR/BARC stack. In other examples, the patterned PR layer 440 can be or include a DUV stack which includes a PR layer under a BARC layer under a dielectric ARC (DARC) layer to provide a PR/BARC/DARC stack.

The metal or metal nitride layer 404 can be or include metal oxide, metal nitride, silicon oxide, silicon nitride, silicon oxynitride, dopants thereof, or any combination thereof. The metal or metal nitride layer 404 can be or include a stack disposed on or over a substrate 402. In one or more examples, the stack contains alternating layers of silicon oxide and layers of silicon nitride. The substrate 402 can be or include any type of substrate including the substrate 102 described and discussed above.

In some examples, the metal or metal nitride layer 404 can be or include one or more metal layers. In one or more examples, the metal layer can be or include metallic titanium, metallic tantalum, metallic tungsten, alloys thereof of any combination thereof. In other examples, the metal or metal nitride layer 404 can be or include a metal nitride layer, and the metal nitride layer can be or include titanium nitride, tantalum nitride, tungsten nitride, alloys thereof of any combination thereof. In some examples, the metal or metal nitride layer 404 can be or include any type of one or more layers including the under layer 104 and/or the metal or metal nitride layer 304 described and discussed above.

In some embodiments, the feature 442 are etched completely through the thickness of the silicon-containing hardmask 430, as depicted in FIG. 4B. Thereafter, the patterned PR layer 440 can be removed from the workpiece 400. The silicon-containing hardmask 430 can be or include silicon oxide, silicon nitride, silicon oxynitride, dopants thereof, or any combination thereof. In one or more examples, the silicon-containing hardmask 430 can be or include any type of hardmask including the silicon-containing hardmask 230 described and discussed above. In some examples, the silicon-containing hardmask 430 can be etched or otherwise removed by exposing the silicon-containing hardmask 430 to one or more fluorocarbon etchants and one or more process gases. The fluorocarbon etchant can be or include tetrafluoromethane, trifluoromethane, difluoromethane, monofluoromethane, octafluorocyclobutane, hexafluoro-1,3-butadiene, or any combination thereof. The process gas can be or include argon, helium, nitrogen (N₂), oxygen (O₂), or any combination thereof.

In one or more embodiments, the patterned PR layer 440 can be from the silicon-containing hardmask 430 includes exposing the patterned PR layer 440 to an etching process. In some examples, the etching process includes exposing the patterned PR layer 440 to a combination of one or more halogen-containing compounds and at least one of oxygen (O₂), argon, helium, or combination thereof. The halogen-containing compound can be or include chloride (Cl₂), hydrogen bromide (HBr), or any combination thereof. In other embodiments, the patterned PR layer 440 can be removed from the silicon-containing hardmask 430 by exposing the patterned PR layer 440 to a polishing process. The polishing process can be a chemical mechanical polishing (CMP) process.

A carbon hardmask layer 410 can be deposited or otherwise formed onto upper surfaces of the patterned PR layer 440 while depositing the carbon hardmask layer 410 into the features 442 of the patterned PR layer 440, as depicted in FIG. 4C. The carbon hardmask layer 410 can have the compositions and properties and be deposited or otherwise formed by the same processes as the carbon hardmask layer 110 described and discussed above.

A photoresist-antireflective coating (PR-ARC) layer 450 can be deposited, formed, or otherwise disposed one or more first portions of the carbon hardmask layer 410 while leaving exposed one or more second portions of the carbon hardmask layer 410, as depicted in FIG. 4D. The PR-ARC layer 450 can be produced by an EUV lithography process and/or a DUV lithography process. In one or more examples, the PR-ARC layer 450 can be or include a photoresist layer, a bottom antireflective coating (BARC) layer, and a dielectric antireflective coating (DARC) layer. In other examples, the PR-ARC layer 450 can be or include a photoresist layer and a silicon-containing antireflective coating (SiARC) layer.

The second portion of the carbon hardmask layer 410 is etched or otherwise removed while maintaining the PR-ARC layer 450 and the first portion of the carbon hardmask layer 410 on the workpiece 400 during a first mask etch process, as depicted in FIG. 4E. In one or more examples, the first mask etch process includes exposing the workpiece 400 to an ICP while removing the second portion of the carbon hardmask layer 410 and maintaining the PR-ARC layer 450 and the first portion of the carbon hardmask layer 410 on the workpiece 400. In some examples, the ICP contains or can be formed from a mixture of oxygen (O₂) and argon.

The PR-ARC layer 450 is etched or otherwise removed while maintaining the first portion of the carbon hardmask layer 410 on the workpiece 400 during a second mask etch process, as depicted in FIG. 4F. The second mask etch process includes exposing the workpiece 400 to a selective removal process or a wet etch process to remove the PR-ARC layer 450 while maintaining the first portion of the carbon hardmask layer 410 on the workpiece 400.

FIGS. 4F-4G depict the treatment or transition of the carbon hardmask layer 410 (FIG. 4F) to produce the aluminum oxide carbon hybrid hardmask 420 (FIG. 4G) via the SIS process. The SIS process is selective to the carbon hardmask layer 410 while being unreactive or substantially unreactive to the other exposed surfaces and layers, such as the metal or metal nitride layer 404 and the silicon-containing hardmask 430 on the workpiece 400. The aluminum oxide carbon hybrid hardmask 420 is denser than the carbon hardmask layer 410. The aluminum oxide carbon hybrid hardmask 420 can have the compositions and properties as the aluminum oxide carbon hybrid hardmask 120 described and discussed above.

The aluminum oxide carbon hybrid hardmask 420 contains at least aluminum, oxygen, and carbon. In one or more embodiments, the aluminum oxide carbon hybrid hardmask 420 can contain aluminum in a range from about 3 at %, about 4 at %, about 5 at %, about 6 at %, about 8 at %, or about 10 at % to about 12 at %, about 14 at %, about 15 at %, about 16 at %, about 18 at %, about 20 at %, about 22 at %, or about 25 at %. For example, the aluminum oxide carbon hybrid hardmask 420 can contain aluminum in a range from about 3 at % to about 25 at %, about 3 at % to about 20 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 420 can contain oxygen in a range from about 3 at %, about 4 at %, about 5 at %, about 6 at %, about 8 at %, or about 10 at % to about 12 at %, about 15 at %, about 18 at %, about 20 at %, about 22 at %, about 25 at %, about 28 at %, about 30 at %, or about 35 at %. For example, the aluminum oxide carbon hybrid hardmask 420 can contain oxygen in a range from about 3 at % to about 35 at %, about 3 at % to about 30 at %, about 3 at % to about 25 at %, about 3 at % to about 20 at %, about 5 at % to about 35 at %, about 5 at % to about 30 at %, about 5 at % to about 25 at %, about 5 at % to about 20 at %, about 8 at % to about 20 at %, about 10 at % to about 20 at %, about 12 at % to about 20 at %, about 15 at % to about 20 at %, about 18 at % to about 20 at %, about 5 at % to about 30 at %, about 8 at % to about 30 at %, about 10 at % to about 30 at %, about 12 at % to about 30 at %, about 15 at % to about 30 at %, about 18 at % to about 30 at %, about 3 at % to about 15 at %, about 5 at % to about 15 at %, about 8 at % to about 15 at %, about 10 at % to about 15 at %, about 12 at % to about 15 at %, about 14 at % to about 15 at %, about 3 at % to about 10 at %, about 5 at % to about 10 at %, or about 8 at % to about 10 at %.

The aluminum oxide carbon hybrid hardmask 420 can contain carbon in a range from about 40 at %, about 45 at %, about 50 at %, about 55 at %, about 60 at %, or about 65 at % to about 70 at %, about 75 at %, about 80 at %, about 85 at %, about 90 at %, or about 95 at %. For example, the aluminum oxide carbon hybrid hardmask 420 can contain carbon in a range from about 40 at % to about 90 at %, about 50 at % to about 90 at %, about 60 at % to about 90 at %, about 70 at % to about 90 at %, about 80 at % to about 90 at %, about 40 at % to about 75 at %, about 50 at % to about 75 at %, about 60 at % to about 75 at %, about 70 at % to about 75 at %, about 40 at % to about 60 at %, about 45 at % to about 60 at %, about 50 at % to about 60 at %, or about 55 at % to about 60 at %.

In one or more examples, the aluminum oxide carbon hybrid hardmask 420 can contain about 5 at % to about 20 at % of aluminum, about 5 at % to about 30 at % of oxygen, and about 50 at % to about 90 at % of carbon. In some examples, the aluminum oxide carbon hybrid hardmask 420 can contain about 10 at % to about 20 at % of aluminum, about 10 at % to about 30 at % of oxygen, and about 50 at % to about 80 at % of carbon. In one or more examples, the aluminum oxide carbon hybrid hardmask 420 can contain about 5 at % to about 10 at % of aluminum, about 5 at % to about 20 at % of oxygen, and about 70 at % to about 90 at % of carbon.

The aluminum oxide carbon hybrid hardmask 420 has a thickness in a range from about 1 μm to about 20 μm, about 2 μm to about 10 μm, or about 3 μm to about 6 μm. The aluminum oxide carbon hybrid hardmask 420 can be or include a patterned layer which contains a feature pattern of features 442, as shown in FIG. 4G. The feature pattern or the features 442 can have a height which the same or less than the thickness of the aluminum oxide carbon hybrid hardmask 420. As such, the feature pattern or the features 442 can have a height in a range from about 1 μm to about 20 μm, about 2 μm to about 10 μm, or about 3 μm to about 6 μm. The feature pattern or the features 442 of the patterned layer or the aluminum oxide carbon hybrid hardmask 420 are separated by vias, gaps, or spaces which can have a width of about 5 nm to about 250 nm, about 10 nm to about 150 nm, or about 20 nm to about 100 nm. The feature pattern or the features 442 can have an aspect ratio of about 20 to about 500, about 30 to about 300, or about 40 to about 200.

Most traditional chemical vapor deposition (CVD) chambers or atomic layer deposition (ALD) chambers can be used as the processing chamber suitable for performing the SIS process described and discussed herein. One example of the processing chamber that may be adapted to benefit from the SIS process is a CENTRIS® Sym3™ etching processing chamber, commercially available from Applied Materials, Inc. An example of a tool or system that benefit from the SIS process is the Centura® system or Endura® system with an iSprint™ ALD/CVD SSW chamber, commercially available from Applied Materials, Inc.

Embodiments of the present disclosure further relate to any one or more of the following examples 1-185.
1. A method of treating a carbon hardmask layer, comprising: positioning a workpiece within a process region of a processing chamber, wherein the workpiece comprises a carbon hardmask layer disposed on or over an underlayer; and treating the carbon hardmask layer by exposing the workpiece to a sequential infiltration synthesis (SIS) process to produce an aluminum oxide carbon hybrid hardmask which is denser than the carbon hardmask layer, wherein the SIS process comprises one or more infiltration cycles, and each of the infiltration cycles comprises: exposing the carbon hardmask layer to an aluminum precursor; infiltrating the carbon hardmask layer with the aluminum precursor via pores contained in the carbon hardmask layer; purging the process region to remove gaseous remnants containing the aluminum precursor; exposing the carbon hardmask layer to an oxidizing agent; infiltrating the carbon hardmask layer with the oxidizing agent via the pores contained in the carbon hardmask layer to produce an aluminum oxide coating disposed on inner surfaces of the carbon hardmask layer; and purging the process region to remove gaseous remnants containing the oxidizing agent.
2. The method according to example 1, wherein the carbon hardmask layer has a thickness of about 1 μm to about 20 μm.
3. The method according to example 1 or 2, wherein the carbon hardmask layer is a patterned layer.
4. The method according to any one of examples 1-3, wherein the patterned layer contains features which have a height of about 1 μm to about 20 μm.
5. The method according to any one of examples 1-4, wherein the patterned layer contains features separated by vias, gaps, or spaces which have a width of about 5 nm to about 250 nm.
6. The method according to any one of examples 1-5, wherein the patterned layer contains features which have an aspect ratio of about 20 to about 500.
7. The method according to any one of examples 1-6, wherein the carbon hardmask layer comprises carbon-containing materials having polar functional groups, and wherein the aluminum oxide coating is disposed on inner surfaces having the polar functional groups.
8. The method according to example 7, wherein the polar functional groups include C—H groups, C—O groups, C═O groups, or any combination thereof.
9. The method according to any one of examples 1-8, wherein the carbon hardmask layer is deposited by a thermal chemical vapor deposition (CVD) process, a plasma-enhanced CVD (PE-CVD) process, a flowable CVD (FCVD) process, or a spin-on process.
10. The method according to any one of examples 1-9, wherein the carbon hardmask layer comprises about 30 atomic percent (at %) to about 80 at % of carbon, about 10 at % to about 50 at % of hydrogen, and about 10 at % to about 20 at % of oxygen.
11. The method according to any one of examples 1-10, wherein the aluminum oxide carbon hybrid hardmask comprises about 5 at % to about 20 at % of aluminum and about 5 at % to about 30 at % of oxygen.
12. The method according to any one of examples 1-11, wherein the aluminum oxide carbon hybrid hardmask further comprises about 50 at % to about 90 at % of carbon.
13. The method according to any one of examples 1-12, wherein the underlayer comprises metal oxide, metal nitride, silicon oxide, silicon nitride, silicon oxynitride, dopants thereof, or any combination thereof.
14. The method according to any one of examples 1-13, wherein the underlayer comprises a stack disposed on or over a substrate.
15. The method according to example 14, wherein the stack comprises alternating layers of silicon oxide and layers of silicon nitride.
16. The method according to any one of examples 1-15, wherein the aluminum precursor comprises an alkylaluminum compound.
17. The method according to any one of examples 1-16, wherein the oxidizing agent comprises water, ozone, atomic oxygen, oxygen plasma, hydrogen peroxide, or any combination thereof.
18. The method according to any one of examples 1-17, wherein the aluminum precursor comprises trimethyl aluminum and the oxidizing agent comprises water.
19. The method according to any one of examples 1-18, wherein the infiltration cycle is repeated 2 times to about 50 times during the SIS process.
20. The method according to any one of examples 1-19, wherein the process region of the processing chamber is at a pressure of about 0.01 Torr to about 250 Torr during the SIS process.
21. The method according to any one of examples 1-20, wherein the carbon hardmask layer is exposed to the aluminum precursor for about 1 minute to about 10 minutes while infiltrating the carbon hardmask layer with the aluminum precursor during each of the infiltration cycles.
22. The method according to any one of examples 1-21, wherein the carbon hardmask layer is exposed to a purge gas for about 1 minute to about 30 minutes while purging the process region to remove the gaseous remnants containing the aluminum precursor during each of the infiltration cycles.
23. The method according to any one of examples 1-22, wherein the carbon hardmask layer is exposed to the oxidizing agent for about 1 minute to about 10 minutes while infiltrating the carbon hardmask layer with the oxidizing agent during each of the infiltration cycles.
24. The method according to any one of examples 1-23, wherein the carbon hardmask layer is exposed to a purge gas for about 1 minute to about 30 minutes while purging the process region to remove the gaseous remnants containing the oxidizing agent during each of the infiltration cycles.
25. A method of forming a device, comprising: positioning a workpiece within a process region of a processing chamber, wherein the workpiece comprises: a carbon hardmask layer disposed on or over an underlayer; a silicon-containing hardmask disposed on or over the carbon hardmask layer; and a patterned photoresist layer having a feature pattern disposed on the silicon-containing hardmask; etching the silicon-containing hardmask and the carbon hardmask layer to each have the feature pattern of the patterned photoresist layer; treating the carbon hardmask layer by exposing the workpiece to a sequential infiltration synthesis (SIS) process to produce an aluminum oxide carbon hybrid hardmask which is denser than the carbon hardmask layer; and then etching the underlayer to have the feature pattern of the patterned photoresist layer.
26. The method according to example 25, wherein the SIS process comprises one or more infiltration cycles, and each of the infiltration cycles comprises: exposing the carbon hardmask layer to an aluminum precursor; infiltrating the carbon hardmask layer with the aluminum precursor via pores contained in the carbon hardmask layer; purging the process region to remove gaseous remnants containing the aluminum precursor; exposing the carbon hardmask layer to an oxidizing agent; infiltrating the carbon hardmask layer with the oxidizing agent via the pores contained in the carbon hardmask layer to produce an aluminum oxide coating disposed on inner surfaces of the carbon hardmask layer; and purging the process region to remove gaseous remnants containing the oxidizing agent.
27. The method according to example 25 or 26, wherein the aluminum precursor comprises an alkylaluminum compound.
28. The method according to any one of examples 25-27, wherein the oxidizing agent comprises water, ozone, atomic oxygen, oxygen plasma, hydrogen peroxide, or any combination thereof.
29. The method according to any one of examples 25-28, wherein the aluminum precursor comprises trimethyl aluminum and the oxidizing agent comprises water.
30. The method according to any one of examples 25-29, wherein the infiltration cycle is repeated 2 times to about 50 times during the SIS process.
31. The method according to any one of examples 25-30, wherein the process region of the processing chamber is at a pressure of about 0.01 Torr to about 250 Torr during the SIS process.
32. The method according to any one of examples 25-31, wherein the carbon hardmask layer is exposed to the aluminum precursor for about 1 minute to about 10 minutes while infiltrating the carbon hardmask layer with the aluminum precursor during each of the infiltration cycles.
33. The method according to any one of examples 25-32, wherein the carbon hardmask layer is exposed to a purge gas for about 1 minute to about 30 minutes while purging the process region to remove the gaseous remnants containing the aluminum precursor during each of the infiltration cycles.
34. The method according to any one of examples 25-33, wherein the carbon hardmask layer is exposed to the oxidizing agent for about 1 minute to about 10 minutes while infiltrating the carbon hardmask layer with the oxidizing agent during each of the infiltration cycles.
35. The method according to any one of examples 25-34, wherein the carbon hardmask layer is exposed to a purge gas for about 1 minute to about 30 minutes while purging the process region to remove the gaseous remnants containing the oxidizing agent during each of the infiltration cycles.
36. The method according to any one of examples 25-35, wherein the patterned photoresist layer is produced by an extreme ultraviolet (EUV) lithography process or a deep ultraviolet (DUV) lithography process.
37. The method according to any one of examples 25-36, wherein the silicon-containing hardmask comprises silicon oxide, silicon nitride, silicon oxynitride, dopants thereof, or any combination thereof.
38. The method according to any one of examples 25-37, wherein the device is a memory device, a logic device, or a microelectronic device.
39. The method according to any one of examples 25-38, wherein the feature pattern is etched completely through a thickness of the silicon-containing hardmask.
40. The method according to any one of examples 25-39, wherein etching the silicon-containing hardmask further comprises exposing the silicon-containing hardmask to a fluorocarbon etchant and a process gas.
41. The method according to example 40, wherein the fluorocarbon etchant comprising tetrafluoromethane, trifluoromethane, difluoromethane, monofluoromethane, octafluorocyclobutane, hexafluoro-1,3-butadiene, or any combination thereof, and the process gas comprises argon, helium, nitrogen (N₂), oxygen (O₂), or any combination thereof.
42. The method according to any one of examples 25-41, wherein the feature pattern is etched completely through a thickness of the carbon hardmask layer.
43. The method according to any one of examples 25-42, wherein etching the carbon hardmask layer further comprises exposing the carbon hardmask layer to an etchant gas and a passivation gas.
44. The method according to example 43, wherein the etchant gas comprises argon, oxygen, or a combination thereof, and the passivation gas comprises methane, sulfur dioxide, carbonyl sulfide, or any combination thereof.
45. The method according to any one of examples 25-44, wherein the feature pattern is partially etched into a thickness of the underlayer.
46. The method according to any one of examples 25-45, wherein partially etching the underlayer further comprises exposing the underlayer to a fluorocarbon etchant and a process gas.
47. The method according to example 46, wherein the fluorocarbon etchant comprising tetrafluoromethane, trifluoromethane, difluoromethane, monofluoromethane, octafluorocyclobutane, hexafluoro-1,3-butadiene, or any combination thereof, and the process gas comprises argon, helium, nitrogen (N₂), oxygen (O₂), or any combination thereof.
48. The method according to any one of examples 25-47, wherein the carbon hardmask layer has a thickness of about 1 μm to about 20 μm.
49. The method according to any one of examples 25-48, wherein the carbon hardmask layer is a patterned layer.
50. The method according to any one of examples 25-49, wherein the patterned layer contains features which have a height of about 1 μm to about 20 μm.
51. The method according to any one of examples 25-50, wherein the patterned layer contains features separated by vias, gaps, or spaces which have a width of about 5 nm to about 250 nm.
52. The method according to any one of examples 25-51, wherein the patterned layer contains features which have an aspect ratio of about 20 to about 500.
53. The method according to any one of examples 25-52, wherein the carbon hardmask layer comprises carbon-containing materials having polar functional groups, and wherein the aluminum oxide coating is disposed on inner surfaces having the polar functional groups.
54. The method according to example 53, wherein the polar functional groups include C—H groups, C—O groups, C═O groups, or any combination thereof.
55. The method according to any one of examples 25-54, wherein the carbon hardmask layer is deposited by a thermal chemical vapor deposition (CVD) process, a plasma-enhanced CVD (PE-CVD) process, a flowable CVD (FCVD) process, or a spin-on process.
56. The method according to any one of examples 25-55, wherein the carbon hardmask layer comprises about 30 atomic percent (at %) to about 80 at % of carbon, about 10 at % to about 50 at % of hydrogen, and about 10 at % to about 20 at % of oxygen.
57. The method according to any one of examples 25-56, wherein the aluminum oxide carbon hybrid hardmask comprises about 5 at % to about 20 at % of aluminum and about 5 at % to about 30 at % of oxygen.
58. The method according to any one of examples 25-57, wherein the aluminum oxide carbon hybrid hardmask further comprises about 50 at % to about 90 at % of carbon.
59. The method according to any one of examples 25-58, wherein the underlayer comprises metal oxide, metal nitride, silicon oxide, silicon nitride, silicon oxynitride, dopants thereof, or any combination thereof.
60. The method according to any one of examples 25-59, wherein the underlayer comprises a stack disposed on or over a substrate.
61. The method according to example 60, wherein the stack comprises alternating layers of silicon oxide and layers of silicon nitride.
62. A method of forming a device, comprising: positioning a workpiece within a process region of a processing chamber, wherein the workpiece comprises: a metal or metal nitride layer disposed on or over a substrate; a silicon-containing hardmask disposed on or over the metal or metal nitride layer; and a patterned photoresist layer having a feature pattern disposed on the silicon-containing hardmask; etching the silicon-containing hardmask to have the feature pattern of the patterned photoresist layer; removing the patterned photoresist layer from the silicon-containing hardmask; depositing a carbon hardmask layer at least into the feature pattern of the patterned photoresist layer; treating the carbon hardmask layer by exposing the workpiece to a sequential infiltration synthesis (SIS) process to produce an aluminum oxide carbon hybrid hardmask which is denser than the carbon hardmask layer; and then etching the silicon-containing hardmask to produce a reverse pattern within the aluminum oxide carbon hybrid hardmask.
63. The method according to example 62, wherein the SIS process comprises one or more infiltration cycles, and each of the infiltration cycles comprises: exposing the carbon hardmask layer to an aluminum precursor; infiltrating the carbon hardmask layer with the aluminum precursor via pores contained in the carbon hardmask layer; purging the process region to remove gaseous remnants containing the aluminum precursor; exposing the carbon hardmask layer to an oxidizing agent; infiltrating the carbon hardmask layer with the oxidizing agent via the pores contained in the carbon hardmask layer to produce an aluminum oxide coating disposed on inner surfaces of the carbon hardmask layer; and purging the process region to remove gaseous remnants containing the oxidizing agent.
64. The method according to example 62 or 63, wherein the aluminum precursor comprises an alkylaluminum compound.
65. The method according to any one of examples 62-64, wherein the oxidizing agent comprises water, ozone, atomic oxygen, oxygen plasma, hydrogen peroxide, or any combination thereof.
66. The method according to any one of examples 62-65, wherein the aluminum precursor comprises trimethyl aluminum and the oxidizing agent comprises water.
67. The method according to any one of examples 62-66, wherein the infiltration cycle is repeated 2 times to about 50 times during the SIS process.
68. The method according to any one of examples 62-67, wherein the process region of the processing chamber is at a pressure of about 0.01 Torr to about 250 Torr during the SIS process.
69. The method according to any one of examples 62-68, wherein the carbon hardmask layer is exposed to the aluminum precursor for about 1 minute to about 10 minutes while infiltrating the carbon hardmask layer with the aluminum precursor during each of the infiltration cycles.
70. The method according to any one of examples 62-69, wherein the carbon hardmask layer is exposed to a purge gas for about 1 minute to about 30 minutes while purging the process region to remove the gaseous remnants containing the aluminum precursor during each of the infiltration cycles.
71. The method according to any one of examples 62-70, wherein the carbon hardmask layer is exposed to the oxidizing agent for about 1 minute to about 10 minutes while infiltrating the carbon hardmask layer with the oxidizing agent during each of the infiltration cycles.
72. The method according to any one of examples 62-71, wherein the carbon hardmask layer is exposed to a purge gas for about 1 minute to about 30 minutes while purging the process region to remove the gaseous remnants containing the oxidizing agent during each of the infiltration cycles.
73. The method according to any one of examples 62-72, wherein the patterned photoresist layer is produced by an extreme ultraviolet (EUV) lithography process or a deep ultraviolet (DUV) lithography process.
74. The method according to any one of examples 62-73, wherein the silicon-containing hardmask comprises silicon oxide, silicon nitride, silicon oxynitride, dopants thereof, or any combination thereof.
75. The method according to any one of examples 62-74, wherein the device is a memory device, a logic device, or a microelectronic device.
76. The method according to any one of examples 62-75, wherein the feature pattern is etched completely through a thickness of the silicon-containing hardmask.
77. The method according to any one of examples 62-76, wherein etching the silicon-containing hardmask further comprises exposing the silicon-containing hardmask to a fluorocarbon etchant and a process gas.
78. The method according to example 77, wherein the fluorocarbon etchant comprising tetrafluoromethane, trifluoromethane, difluoromethane, monofluoromethane, octafluorocyclobutane, hexafluoro-1,3-butadiene, or any combination thereof, and the process gas comprises argon, helium, nitrogen (N₂), oxygen (O₂), or any combination thereof.
79. The method according to any one of examples 62-78, wherein removing the patterned photoresist layer from the silicon-containing hardmask comprises exposing the patterned photoresist layer to an etching process.
80. The method according to example 79, wherein the etching process comprises exposing the patterned photoresist layer to a combination of a halogen-containing compound and at least one of oxygen (O₂), argon, helium, or combination thereof.
81. The method according to example 80, wherein the halogen-containing compound comprises chloride (Cl₂), hydrogen bromide (HBr), or any combination thereof.
82. The method according to any one of examples 62-81, wherein removing the patterned photoresist layer from the silicon-containing hardmask comprises exposing the patterned photoresist layer to a polishing process.
83. The method according to example 82, wherein the polishing process comprises a chemical mechanical polishing (CMP) process.
84. The method according to any one of examples 62-83, further comprising depositing the carbon hardmask layer onto upper surfaces of the patterned photoresist layer while depositing the carbon hardmask layer into the feature pattern of the patterned photoresist layer.
85. The method according to example 84, further comprising removing the carbon hardmask layer from the upper surfaces of the patterned photoresist layer before treating the carbon hardmask layer to the SIS process.
86. The method according to example 85, wherein removing the carbon hardmask layer from the upper surfaces of the patterned photoresist layer comprises a polishing process.
87. The method according to any one of examples 62-86, wherein the carbon hardmask layer has a thickness of about 1 μm to about 20 μm.
88. The method according to any one of examples 62-87, wherein the carbon hardmask layer is a patterned layer.
89. The method according to example 88, wherein the patterned layer contains features which have a height of about 1 μm to about 20 μm.
90. The method according to example 88 or 89, wherein the patterned layer contains features separated by vias, gaps, or spaces which have a width of about 5 nm to about 250 nm.
91. The method according to any one of examples 88-90, wherein the patterned layer contains features which have an aspect ratio of about 20 to about 500.
92. The method according to any one of examples 62-91, wherein the carbon hardmask layer comprises carbon-containing materials having polar functional groups, and wherein the aluminum oxide coating is disposed on inner surfaces having the polar functional groups.
93. The method according to example 92, wherein the polar functional groups include C—H groups, C—O groups, C═O groups, or any combination thereof.
94. The method according to any one of examples 62-93, wherein the carbon hardmask layer is deposited by a thermal chemical vapor deposition (CVD) process, a plasma-enhanced CVD (PE-CVD) process, a flowable CVD (FCVD) process, or a spin-on process.
95. The method according to any one of examples 62-94, wherein the carbon hardmask layer comprises about 30 atomic percent (at %) to about 80 at % of carbon, about 10 at % to about 50 at % of hydrogen, and about 10 at % to about 20 at % of oxygen.
96. The method according to any one of examples 62-95, wherein the aluminum oxide carbon hybrid hardmask comprises about 5 at % to about 20 at % of aluminum and about 5 at % to about 30 at % of oxygen.
97. The method according to any one of examples 62-96, wherein the aluminum oxide carbon hybrid hardmask further comprises about 50 at % to about 90 at % of carbon.
98. The method according to any one of examples 62-97, wherein the silicon-containing hardmask is etched to produce the reverse pattern within the aluminum oxide carbon hybrid hardmask further comprises exposing the workpiece to an inductively coupled plasma (ICP) to remove the silicon-containing hardmask while maintaining the aluminum oxide carbon hybrid hardmask on the metal or metal nitride layer.
99. The method according to example 98, wherein the ICP comprises a mixture of oxygen (O₂) and argon.
100. The method according to any one of examples 62-99, wherein the silicon-containing hardmask is etched to produce the reverse pattern within the aluminum oxide carbon hybrid hardmask further comprises exposing the workpiece to a selective removal process or a wet etch process to remove the silicon-containing hardmask while maintaining the aluminum oxide carbon hybrid hardmask on the metal or metal nitride layer.
101. The method according to any one of examples 62-100, wherein the metal or metal nitride layer comprises a metal layer, and wherein the metal layer comprises metallic titanium, metallic tantalum, metallic tungsten, alloys thereof of any combination thereof.
102. The method according to any one of examples 62-101, wherein the metal or metal nitride layer comprises a metal nitride layer, and wherein the metal nitride layer comprises titanium nitride, tantalum nitride, tungsten nitride, alloys thereof of any combination thereof.
103. A method of forming a device, comprising: positioning a workpiece within a process region of a processing chamber, wherein the workpiece comprises: a metal or metal nitride layer disposed on or over a substrate; a silicon-containing hardmask disposed on or over the metal or metal nitride layer; and a patterned photoresist layer having a feature pattern disposed on the silicon-containing hardmask; etching the silicon-containing hardmask to have the feature pattern of the patterned photoresist layer; removing the patterned photoresist layer from the silicon-containing hardmask; depositing a carbon hardmask layer into the feature pattern of the patterned photoresist layer and onto an upper surface of the patterned photoresist layer; depositing a photoresist-antireflective coating (PR-ARC) layer on a first portion of the carbon hardmask layer while leaving exposed a second portion of the carbon hardmask layer; etching the second portion of the carbon hardmask layer while maintaining the PR-ARC layer and the first portion of the carbon hardmask layer on the workpiece during a first mask etch process; etching the PR-ARC layer while maintaining the first portion of the carbon hardmask layer on the workpiece during a second mask etch process; and treating the first portion of the carbon hardmask layer by exposing the workpiece to a sequential infiltration synthesis (SIS) process to produce an aluminum oxide carbon hybrid hardmask which is denser than the carbon hardmask layer.
104. The method according to example 103, wherein the SIS process comprises one or more infiltration cycles, and each of the infiltration cycles comprises: exposing the carbon hardmask layer to an aluminum precursor; infiltrating the carbon hardmask layer with the aluminum precursor via pores contained in the carbon hardmask layer; purging the process region to remove gaseous remnants containing the aluminum precursor; exposing the carbon hardmask layer to an oxidizing agent; infiltrating the carbon hardmask layer with the oxidizing agent via the pores contained in the carbon hardmask layer to produce an aluminum oxide coating disposed on inner surfaces of the carbon hardmask layer; and purging the process region to remove gaseous remnants containing the oxidizing agent.
105. The method according to example 103 or 104, wherein the aluminum precursor comprises an alkylaluminum compound.
106. The method according to any one of examples 103-105, wherein the oxidizing agent comprises water, ozone, atomic oxygen, oxygen plasma, hydrogen peroxide, or any combination thereof.
107. The method according to any one of examples 103-106, wherein the aluminum precursor comprises trimethyl aluminum and the oxidizing agent comprises water.
108. The method according to any one of examples 103-107, wherein the infiltration cycle is repeated 2 times to about 50 times during the SIS process.
109. The method according to any one of examples 103-108, wherein the process region of the processing chamber is at a pressure of about 0.01 Torr to about 250 Torr during the SIS process.
110. The method according to any one of examples 103-109, wherein the carbon hardmask layer is exposed to the aluminum precursor for about 1 minute to about 10 minutes while infiltrating the carbon hardmask layer with the aluminum precursor during each of the infiltration cycles.
111. The method according to any one of examples 103-110, wherein the carbon hardmask layer is exposed to a purge gas for about 1 minute to about 30 minutes while purging the process region to remove the gaseous remnants containing the aluminum precursor during each of the infiltration cycles.
112. The method according to any one of examples 103-111, wherein the carbon hardmask layer is exposed to the oxidizing agent for about 1 minute to about 10 minutes while infiltrating the carbon hardmask layer with the oxidizing agent during each of the infiltration cycles.
113. The method according to any one of examples 103-112, wherein the carbon hardmask layer is exposed to a purge gas for about 1 minute to about 30 minutes while purging the process region to remove the gaseous remnants containing the oxidizing agent during each of the infiltration cycles.
114. The method according to any one of examples 103-113, wherein the patterned photoresist layer is produced by an extreme ultraviolet (EUV) lithography process or a deep ultraviolet (DUV) lithography process.
115. The method according to any one of examples 103-114, wherein the silicon-containing hardmask comprises silicon oxide, silicon nitride, silicon oxynitride, dopants thereof, or any combination thereof.
116. The method according to any one of examples 103-115, wherein the device is a memory device, a logic device, or a microelectronic device.
117. The method according to any one of examples 103-116, wherein the feature pattern is etched completely through a thickness of the silicon-containing hardmask.
118. The method according to any one of examples 103-117, wherein etching the silicon-containing hardmask further comprises exposing the silicon-containing hardmask to a fluorocarbon etchant and a process gas.
119. The method according to example 118, wherein the fluorocarbon etchant comprising tetrafluoromethane, trifluoromethane, difluoromethane, monofluoromethane, octafluorocyclobutane, hexafluoro-1,3-butadiene, or any combination thereof, and the process gas comprises argon, helium, nitrogen (N₂), oxygen (O₂), or any combination thereof.
120. The method according to any one of examples 103-119, wherein removing the patterned photoresist layer from the silicon-containing hardmask comprises exposing the patterned photoresist layer to an etching process.
121. The method according to example 120, wherein the etching process comprises exposing the patterned photoresist layer to a combination of a halogen-containing compound and at least one of oxygen (O₂), argon, helium, or combination thereof.
122. The method according to example 121, wherein the halogen-containing compound comprises chloride (Cl₂), hydrogen bromide (HBr), or any combination thereof.
123. The method according to any one of examples 103-122, wherein removing the patterned photoresist layer from the silicon-containing hardmask comprises exposing the patterned photoresist layer to a polishing process.
124. The method according to example 123, wherein the polishing process comprises a chemical mechanical polishing (CMP) process.
125. The method according to any one of examples 103-124, wherein the first mask etch process comprises exposing the workpiece to an inductively coupled plasma (ICP) while removing the second portion of the carbon hardmask layer and maintaining the PR-ARC layer and the first portion of the carbon hardmask layer on the workpiece.
126. The method according to example 125, wherein the ICP comprises a mixture of oxygen (O₂) and argon.
127. The method according to any one of examples 103-126, wherein the second mask etch process comprises exposing the workpiece to a selective removal process or a wet etch process to remove the PR-ARC layer while maintaining the first portion of the carbon hardmask layer on the workpiece.
128. The method according to any one of examples 103-127, wherein the carbon hardmask layer has a thickness of about 1 μm to about 20 μm.
129. The method according to any one of examples 103-128, wherein the carbon hardmask layer is a patterned layer.
130. The method according to example 129, wherein the patterned layer contains features which have a height of about 1 μm to about 20 μm.
131. The method according to example 129 or 130, wherein the patterned layer contains features separated by vias, gaps, or spaces which have a width of about 5 nm to about 250 nm.
132. The method according to any one of examples 129-131, wherein the patterned layer contains features which have an aspect ratio of about 20 to about 500.
133. The method according to any one of examples 103-132, wherein the carbon hardmask layer comprises carbon-containing materials having polar functional groups, and wherein the aluminum oxide coating is disposed on inner surfaces having the polar functional groups.
134. The method according to example 133, wherein the polar functional groups include C—H groups, C—O groups, C═O groups, or any combination thereof.
135. The method according to any one of examples 103-134, wherein the carbon hardmask layer is deposited by a thermal chemical vapor deposition (CVD) process, a plasma-enhanced CVD (PE-CVD) process, a flowable CVD (FCVD) process, or a spin-on process.
136. The method according to any one of examples 103-135, wherein the carbon hardmask layer comprises about 30 atomic percent (at %) to about 80 at % of carbon, about 10 at % to about 50 at % of hydrogen, and about 10 at % to about 20 at % of oxygen.
137. The method according to any one of examples 103-136, wherein the aluminum oxide carbon hybrid hardmask comprises about 5 at % to about 20 at % of aluminum and about 5 at % to about 30 at % of oxygen.
138. The method according to any one of examples 103-137, wherein the aluminum oxide carbon hybrid hardmask further comprises about 50 at % to about 90 at % of carbon.
139. The method according to any one of examples 103-138, wherein the metal or metal nitride layer comprises a metal layer, and wherein the metal layer comprises metallic titanium, metallic tantalum, metallic tungsten, alloys thereof of any combination thereof.
140. The method according to any one of examples 103-139, wherein the metal or metal nitride layer comprises a metal nitride layer, and wherein the metal nitride layer comprises titanium nitride, tantalum nitride, tungsten nitride, alloys thereof of any combination thereof.
141. The method according to any one of examples 103-140, wherein the PR-ARC layer is produced by an extreme ultraviolet (EUV) lithography process.
142. The method according to any one of examples 103-141, wherein the PR-ARC layer comprises a photoresist layer, a bottom antireflective coating (BARC) layer, and a dielectric antireflective coating (DARC) layer.
143. The method according to any one of examples 103-142, wherein the PR-ARC layer comprises a photoresist layer and a silicon-containing antireflective coating (SiARC) layer.
144. A workpiece and/or a device prepared, fabricated, processed, or otherwise made by the method according to any one of examples 1-143 and/or depicted in any of the Figures.
145. A workpiece and/or a device, comprising: an underlayer disposed on a substrate, and an aluminum oxide carbon hybrid hardmask disposed on the underlayer, wherein the aluminum oxide carbon hybrid hardmask comprises features.
146. The workpiece and/or the device according to example 145, wherein the aluminum oxide carbon hybrid hardmask has a thickness of about 1 μm to about 20 μm.
147. The workpiece and/or the device according to example 145 or 146, wherein the aluminum oxide carbon hybrid hardmask contains features which have a height of about 1 μm to about 20 μm.
148. The workpiece and/or the device according to any one of examples 145-147, wherein the aluminum oxide carbon hybrid hardmask contains features separated by vias, gaps, or spaces which have a width of about 5 nm to about 250 nm.
149. The workpiece and/or the device according to any one of examples 145-148, wherein the features have an aspect ratio of about 20 to about 500.
150. The workpiece and/or the device according to any one of examples 145-149, wherein the aluminum oxide carbon hybrid hardmask comprises about 5 at % to about 20 at % of aluminum and about 5 at % to about 30 at % of oxygen.
151. The workpiece and/or the device according to any one of examples 145-150, wherein the aluminum oxide carbon hybrid hardmask further comprises about 50 at % to about 90 at % of carbon.
152. The workpiece and/or the device according to any one of examples 145-151, wherein the underlayer comprises metal oxide, metal nitride, silicon oxide, silicon nitride, silicon oxynitride, dopants thereof, or any combination thereof.
153. The workpiece and/or the device according to any one of examples 145-152, wherein the underlayer comprises a stack disposed on or over a substrate.
154. The workpiece and/or the device according to example 153, wherein the stack comprises alternating layers of silicon oxide and layers of silicon nitride.
155. A workpiece and/or a device, comprising: an underlayer disposed on a substrate, an aluminum oxide carbon hybrid hardmask disposed on the underlayer, a silicon-containing hardmask disposed on the aluminum oxide carbon hybrid hardmask, and a patterned photoresist (PR) layer disposed on the silicon-containing hardmask, wherein features extend through at least the aluminum oxide carbon hybrid hardmask, the silicon-containing hardmask, and the patterned PR layer.
156. The workpiece and/or the device according to example 155, wherein the features extend into at least a portion of the underlayer.
157. The workpiece and/or the device according to example 155 or 156, wherein the aluminum oxide carbon hybrid hardmask has a thickness of about 1 μm to about 20 μm.
158. The workpiece and/or the device according to any one of examples 155-157, wherein the features have a height of about 1 μm to about 20 μm.
159. The workpiece and/or the device according to any one of examples 155-158, wherein the features are separated by vias, gaps, or spaces which have a width of about 5 nm to about 250 nm.
160. The workpiece and/or the device according to any one of examples 155-159, wherein the features have an aspect ratio of about 20 to about 500.
161. The workpiece and/or the device according to any one of examples 155-160, wherein the aluminum oxide carbon hybrid hardmask comprises about 5 at % to about 20 at % of aluminum and about 5 at % to about 30 at % of oxygen.
162. The workpiece and/or the device according to any one of examples 155-161, wherein the aluminum oxide carbon hybrid hardmask further comprises about 50 at % to about 90 at % of carbon.
163. The workpiece and/or the device according to any one of examples 155-162, wherein the underlayer comprises metal oxide, metal nitride, silicon oxide, silicon nitride, silicon oxynitride, dopants thereof, or any combination thereof.
164. The workpiece and/or the device according to any one of examples 155-163, wherein the underlayer comprises a stack disposed on or over a substrate.
165. The workpiece and/or the device according to example 164, wherein the stack comprises alternating layers of silicon oxide and layers of silicon nitride.
166. A workpiece and/or a device, comprising: a metal or metal nitride layer disposed on a substrate, and an aluminum oxide carbon hybrid hardmask disposed on the metal or metal nitride layer, wherein the aluminum oxide carbon hybrid hardmask comprises features.
167. The workpiece and/or the device according to example 166, wherein the aluminum oxide carbon hybrid hardmask has a thickness of about 1 μm to about 20 μm.
168. The workpiece and/or the device according to example 166 or 167, wherein the aluminum oxide carbon hybrid hardmask contains features which have a height of about 1 μm to about 20 μm.
169. The workpiece and/or the device according to any one of examples 166-168, wherein the aluminum oxide carbon hybrid hardmask contains features separated by vias, gaps, or spaces which have a width of about 5 nm to about 250 nm.
170. The workpiece and/or the device according to any one of examples 166-169, wherein the features have an aspect ratio of about 20 to about 500.
171. The workpiece and/or the device according to any one of examples 166-170, wherein the aluminum oxide carbon hybrid hardmask comprises about 5 at % to about 20 at % of aluminum and about 5 at % to about 30 at % of oxygen.
172. The workpiece and/or the device according to any one of examples 166-171, wherein the aluminum oxide carbon hybrid hardmask further comprises about 50 at % to about 90 at % of carbon.
173. The workpiece and/or the device according to any one of examples 166-172, wherein the metal or metal nitride layer comprises a metal layer, and wherein the metal layer comprises metallic titanium, metallic tantalum, metallic tungsten, alloys thereof of any combination thereof.
174. The workpiece and/or the device according to any one of examples 166-173, wherein the metal or metal nitride layer comprises a metal nitride layer, and wherein the metal nitride layer comprises titanium nitride, tantalum nitride, tungsten nitride, alloys thereof of any combination thereof.
175. A workpiece and/or a device, comprising: a metal or metal nitride layer disposed on a substrate, a silicon-containing hardmask disposed on the metal or metal nitride layer, and an aluminum oxide carbon hybrid hardmask disposed on the silicon-containing hardmask and the metal or metal nitride layer, wherein the aluminum oxide carbon hybrid hardmask comprises features.
176. The workpiece and/or the device according to example 175, wherein the aluminum oxide carbon hybrid hardmask has a thickness of about 1 μm to about 20 μm.
177. The workpiece and/or the device according to example 175 or 176, wherein the aluminum oxide carbon hybrid hardmask contains features which have a height of about 1 μm to about 20 μm.
178. The workpiece and/or the device according to any one of examples 175-177, wherein the aluminum oxide carbon hybrid hardmask contains features separated by vias, gaps, or spaces which have a width of about 5 nm to about 250 nm.
179. The workpiece and/or the device according to any one of examples 175-178, wherein the features have an aspect ratio of about 20 to about 500.
180. The workpiece and/or the device according to any one of examples 175-179, wherein the aluminum oxide carbon hybrid hardmask comprises about 5 at % to about 20 at % of aluminum and about 5 at % to about 30 at % of oxygen.
181. The workpiece and/or the device according to any one of examples 175-180, wherein the aluminum oxide carbon hybrid hardmask further comprises about 50 at % to about 90 at % of carbon.
182. The workpiece and/or the device according to any one of examples 175-181, wherein the metal or metal nitride layer comprises a metal layer, and wherein the metal layer comprises metallic titanium, metallic tantalum, metallic tungsten, alloys thereof of any combination thereof.
183. The workpiece and/or the device according to any one of examples 175-182, wherein the metal or metal nitride layer comprises a metal nitride layer, and wherein the metal nitride layer comprises titanium nitride, tantalum nitride, tungsten nitride, alloys thereof of any combination thereof.
184. The workpiece and/or the device according to any one of examples 175-183, wherein the silicon-containing hardmask comprises silicon oxide, silicon nitride, silicon oxynitride, dopants thereof, or any combination thereof.
185. The workpiece and/or the device according to any one of examples 144-184, wherein the device is a memory device, a logic device, or a microelectronic device.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of forming a device, comprising:
positioning a workpiece within a process region of a processing chamber, wherein the workpiece comprises:
a metal or metal nitride layer disposed on or over a substrate;
a silicon-containing hardmask disposed on or over the metal or metal nitride layer; and
a patterned photoresist layer having a feature pattern disposed on the silicon-containing hardmask;
etching the silicon-containing hardmask to have the feature pattern of the patterned photoresist layer;
removing the patterned photoresist layer from the silicon-containing hardmask;
depositing a carbon hardmask layer at least into the feature pattern of the patterned photoresist layer;
treating the carbon hardmask layer by exposing the workpiece to a sequential infiltration synthesis (SIS) process to produce an aluminum oxide carbon hybrid hardmask which is denser than the carbon hardmask layer; and then
etching the silicon-containing hardmask to produce a reverse pattern within the aluminum oxide carbon hybrid hardmask.

2. The method of claim 1, wherein the SIS process comprises one or more infiltration cycles, and each of the infiltration cycles comprises:
exposing the carbon hardmask layer to an aluminum precursor;
infiltrating the carbon hardmask layer with the aluminum precursor via pores contained in the carbon hardmask layer;
purging the process region to remove gaseous remnants containing the aluminum precursor;
exposing the carbon hardmask layer to an oxidizing agent;
infiltrating the carbon hardmask layer with the oxidizing agent via the pores contained in the carbon hardmask layer to produce an aluminum oxide coating disposed on inner surfaces of the carbon hardmask layer; and
purging the process region to remove gaseous remnants containing the oxidizing agent.

3. The method of claim 2, wherein:
the aluminum precursor comprises an alkylaluminum compound;
the oxidizing agent comprises water, ozone, atomic oxygen, oxygen plasma, hydrogen peroxide, or any combination thereof; and
the infiltration cycle is repeated 2 times to about 50 times during the SIS process.

4. The method of claim 2, wherein:
the process region of the processing chamber is at a pressure of about 0.01 Torr to about 250 Torr during the SIS process;
the carbon hardmask layer is exposed to the aluminum precursor for about 1 minute to about 10 minutes while infiltrating the carbon hardmask layer with the aluminum precursor during each of the infiltration cycles;
the carbon hardmask layer is exposed to a purge gas for about 1 minute to about 30 minutes while purging the process region to remove the gaseous remnants containing the aluminum precursor during each of the infiltration cycles;
the carbon hardmask layer is exposed to the oxidizing agent for about 1 minute to about 10 minutes while infiltrating the carbon hardmask layer with the oxidizing agent during each of the infiltration cycles; and
the carbon hardmask layer is exposed to a purge gas for about 1 minute to about 30 minutes while purging the process region to remove the gaseous remnants containing the oxidizing agent during each of the infiltration cycles.

5. The method of claim 1, wherein removing the patterned photoresist layer from the silicon-containing hardmask comprises exposing the patterned photoresist layer to an etching process, and the etching process comprises exposing the patterned photoresist layer to a combination of a halogen-containing compound and at least one of oxygen (O₂), argon, helium, or combination thereof, wherein the halogen-containing compound comprises chloride (Cl₂), hydrogen bromide (HBr), or any combination thereof.

6. The method of claim 1, further comprising:
depositing the carbon hardmask layer onto upper surfaces of the patterned photoresist layer while depositing the carbon hardmask layer into the feature pattern of the patterned photoresist layer; and
removing the carbon hardmask layer from the upper surfaces of the patterned photoresist layer before treating the carbon hardmask layer to the SIS process, wherein removing the carbon hardmask layer from the upper surfaces of the patterned photoresist layer comprises a polishing process.

7. The method of claim 1, wherein:
the carbon hardmask layer has a thickness of about 1 μm to about 20 μm;
the carbon hardmask layer is a patterned layer;
the patterned layer contains features which have a height of about 1 μm to about 20 μm;
the patterned layer contains features separated by vias, gaps, or spaces which have a width of about 5 nm to about 250 nm; and
the patterned layer contains features which have an aspect ratio of about 20 to about 500.

8. The method of claim 1, wherein:
the carbon hardmask layer comprises carbon-containing materials having polar functional groups;
the aluminum oxide coating is disposed on inner surfaces having the polar functional groups; and
the polar functional groups include C—H groups, C—O groups, C═O groups, or any combination thereof.

9. The method of claim 1, wherein the carbon hardmask layer comprises about 30 atomic percent (at %) to about 80 at % of carbon, about 10 at % to about 50 at % of hydrogen, and about 10 at % to about 20 at % of oxygen; and wherein the aluminum oxide carbon hybrid hardmask comprises about 5 at % to about 20 at % of aluminum, about 5 at % to about 30 at % of oxygen, and about 50 at % to about 90 at % of carbon.

10. The method of claim 1, wherein the silicon-containing hardmask is etched to produce the reverse pattern within the aluminum oxide carbon hybrid hardmask further comprises exposing the workpiece to an inductively coupled plasma (ICP) to remove the silicon-containing hardmask while maintaining the aluminum oxide carbon hybrid hardmask on the metal or metal nitride layer, wherein the ICP comprises a mixture of oxygen (O₂) and argon.

11. A method of forming a device, comprising:
positioning a workpiece within a process region of a processing chamber, wherein the workpiece comprises:
a metal or metal nitride layer disposed on or over a substrate;
a silicon-containing hardmask disposed on or over the metal or metal nitride layer; and
a patterned photoresist layer having a feature pattern disposed on the silicon-containing hardmask;
etching the silicon-containing hardmask to have the feature pattern of the patterned photoresist layer;
removing the patterned photoresist layer from the silicon-containing hardmask;
depositing a carbon hardmask layer into the feature pattern of the patterned photoresist layer and onto an upper surface of the patterned photoresist layer;
depositing a photoresist-antireflective coating (PR-ARC) layer on a first portion of the carbon hardmask layer while leaving exposed a second portion of the carbon hardmask layer;
etching the second portion of the carbon hardmask layer while maintaining the PR-ARC layer and the first portion of the carbon hardmask layer on the workpiece during a first mask etch process;
etching the PR-ARC layer while maintaining the first portion of the carbon hardmask layer on the workpiece during a second mask etch process; and
treating the first portion of the carbon hardmask layer by exposing the workpiece to a sequential infiltration synthesis (SIS) process to produce an aluminum oxide carbon hybrid hardmask which is denser than the carbon hardmask layer.

12. The method of claim 11, wherein the SIS process comprises one or more infiltration cycles, and each of the infiltration cycles comprises:
exposing the carbon hardmask layer to an aluminum precursor;
infiltrating the carbon hardmask layer with the aluminum precursor via pores contained in the carbon hardmask layer;
purging the process region to remove gaseous remnants containing the aluminum precursor;
exposing the carbon hardmask layer to an oxidizing agent;
infiltrating the carbon hardmask layer with the oxidizing agent via the pores contained in the carbon hardmask layer to produce an aluminum oxide coating disposed on inner surfaces of the carbon hardmask layer; and
purging the process region to remove gaseous remnants containing the oxidizing agent.

13. The method of claim 12, wherein:
the aluminum precursor comprises an alkylaluminum compound;
the oxidizing agent comprises water, ozone, atomic oxygen, oxygen plasma, hydrogen peroxide, or any combination thereof; and
the infiltration cycle is repeated 2 times to about 50 times during the SIS process.

14. The method of claim 12, wherein:
the process region of the processing chamber is at a pressure of about 0.01 Torr to about 250 Torr during the SIS process;
the carbon hardmask layer is exposed to the aluminum precursor for about 1 minute to about 10 minutes while infiltrating the carbon hardmask layer with the aluminum precursor during each of the infiltration cycles;
the carbon hardmask layer is exposed to a purge gas for about 1 minute to about 30 minutes while purging the process region to remove the gaseous remnants containing the aluminum precursor during each of the infiltration cycles;
the carbon hardmask layer is exposed to the oxidizing agent for about 1 minute to about 10 minutes while infiltrating the carbon hardmask layer with the oxidizing agent during each of the infiltration cycles; and
the carbon hardmask layer is exposed to a purge gas for about 1 minute to about 30 minutes while purging the process region to remove the gaseous remnants containing the oxidizing agent during each of the infiltration cycles.

15. The method of claim 11, wherein etching the silicon-containing hardmask further comprises exposing the silicon-containing hardmask to a fluorocarbon etchant and a process gas, and wherein the fluorocarbon etchant comprising tetrafluoromethane, trifluoromethane, difluoromethane, monofluoromethane, octafluorocyclobutane, hexafluoro-1,3-butadiene, or any combination thereof, and the process gas comprises argon, helium, nitrogen (N₂), oxygen (O₂), or any combination thereof.

16. The method of claim 11, wherein removing the patterned photoresist layer from the silicon-containing hardmask comprises exposing the patterned photoresist layer to an etching process, and the etching process comprises exposing the patterned photoresist layer to a combination of a halogen-containing compound and at least one of oxygen (O₂), argon, helium, or combination thereof, and wherein the halogen-containing compound comprises chloride (Cl₂), hydrogen bromide (HBr), or any combination thereof.

17. The method of claim 11, wherein the first mask etch process comprises exposing the workpiece to an inductively coupled plasma (ICP) while removing the second portion of the carbon hardmask layer and maintaining the PR-ARC layer and the first portion of the carbon hardmask layer on the workpiece, wherein the ICP comprises a mixture of oxygen (O₂) and argon.

18. The method of claim 11, wherein:
the carbon hardmask layer has a thickness of about 1 μm to about 20 μm;
the carbon hardmask layer is a patterned layer;
the patterned layer contains features which have a height of about 1 μm to about 20 μm;
the patterned layer contains features separated by vias, gaps, or spaces which have a width of about 5 nm to about 250 nm; and
the patterned layer contains features which have an aspect ratio of about 20 to about 500.

19. The method of claim 11, wherein the carbon hardmask layer comprises carbon-containing materials having polar functional groups, and wherein the aluminum oxide coating is disposed on inner surfaces having the polar functional groups, and wherein the polar functional groups include C—H groups, C—O groups, C═O groups, or any combination thereof.

20. The method of claim 11, wherein the carbon hardmask layer comprises about 30 atomic percent (at %) to about 80 at % of carbon, about 10 at % to about 50 at % of hydrogen, and about 10 at % to about 20 at % of oxygen, and wherein the aluminum oxide carbon hybrid hardmask comprises about 5 at % to about 20 at % of aluminum, about 5 at % to about 30 at % of oxygen, and the aluminum oxide carbon hybrid hardmask further comprises about 50 at % to about 90 at % of carbon.
